(19) United States
(12) Patent Application Publication
(10) Pub. No.: US 2022/0384493 A1
(43) Pub. Date: Dec. 1, 2022

(54) SOLID-STATE IMAGING APPARATUS AND DISTANCE MEASUREMENT SYSTEM

(71) Applicant: SONY SEMICONDUCTOR SOLUTIONS CORPORATION, KANAGAWA (JP)

(72) Inventors: YUSUKE TAKATSUKA, TOKYO (JP); YOSHIAKI KITANO, KANAGAWA (JP); AKIRA MATSUMOTO, KANAGAWA (JP)

(21) Appl. No.: 17/755,904

(22) PCT Filed: Sep. 24, 2020
(86) PCT No.: PCT/JP2020/036061

§ 371 Date: May 11, 2022

(30) Foreign Application Priority Data
Nov. 20, 2019 (JP) 2019-209508

(51) Int. Cl. H01L 27/146; G01S 17/08; H04N 5/3745; H01L 31/107; G01S 17/89; H04N 5/376

(52) U.S. Cl. CPC H01L 27/1461; G01S 17/08; H01L 27/14612; H04N 5/37455; H01L 31/107; G01S 17/89; H04N 5/3765; H01L 27/14623

(57) ABSTRACT

It is an object to provide a solid-state imaging apparatus and a distance measurement system that can detect high-frequency pulsed light. The solid-state imaging apparatus includes a plurality of pixels, a drive section, and a time measurement section. Each of the plurality of pixels has a light-receiving element that converts received light into an electric signal. The drive section drives the plurality of pixels by shifting operation timings of the light-receiving elements. The time measurement section is provided such that the electric signal is input from each of the plurality of pixels and measures the time until light emitted from a light source is reflected by a subject and received by the light-receiving element on the basis of the input of the electric signal.

### TECHNICAL FIELD

The present disclosure relates to a solid-state imaging apparatus having a light-receiving element and a distance measurement system using the solid-state imaging apparatus.

### BACKGROUND ART

A distance image sensor that measures a distance by a ToF (Time of Flight) technique has been drawing attention in recent years. For example, a pixel array which is formed such that a plurality of SPAD (Single Photon Avalanche Diode) pixels is arranged planarly by using CMOS (ComplementaryMetalOxideSemiconductor) semiconductor integrated circuit technology can be used as a distance image sensor. In an SPAD pixel, avalanche amplification occurs when a photon enters into a PN junction region having a high electric field with a voltage much larger than a breakdown voltage applied. It is possible to measure the distance with high accuracy by detecting a momentary duration of current flow at that time (refer, for example, to PTL 1 and PTL 2).

### CITATION LIST

### Patent Literature

[PTL 1]

Japanese Patent Laid-Open No. 2013-48278

[PTL 2]

Japanese Patent Laid-Open No. 2015-41746

### SUMMARY

### Technical Problem

However, the SPAD pixel cannot detect light after the end of the avalanche amplification until the SPAD pixel is reset. Accordingly, the SPAD pixel has a problem in that it is difficult to detect high-frequency pulsed light.

It is an object of the present disclosure to provide a solid-state imaging apparatus and a distance measurement system that can detect high-frequency pulsed light.

### Solution to Problem

A solid-state imaging apparatus according to an aspect of the present disclosure includes a plurality of pixels each of which has a light-receiving element that converts received light into an electric signal, a drive section adapted to drive the plurality of pixels by shifting operation timings of the light-receiving elements, and a time measurement section provided such that the electric signal is input from each of the plurality of pixels and adapted to measure time until light emitted from a light source is reflected by a subject and received by the light-receiving element on the basis of the input of the electric signal.

A distance measurement system according to an aspect of the present disclosure includes a light source adapted to emit light onto a subject, and a solid-state imaging apparatus having a plurality of pixels each of which has a light-receiving element that converts received light into an electric signal, a drive section adapted to drive the plurality of pixels by shifting operation timings of the light-receiving elements, and a time measurement section provided such that the electric signal is input from each of the plurality of pixels and adapted to measure time until light emitted from the light source is reflected by the subject and received by the light-receiving element on the basis of the input of the electric signal.

### BRIEF DESCRIPTION OF DRAWINGS

FIG. 1A is a schematic diagram depicting an example of configuration of a distance measurement system according to an embodiment of the present disclosure.

FIG. 1B is a block diagram depicting an example of circuit configuration of the distance measurement system according to the embodiment of the present disclosure.

FIG. 2 is a schematic diagram depicting an example of configuration of a solid-state imaging apparatus according to the embodiment of the present disclosure.

FIG. 3 is a plan view depicting an example of configuration of a pixel group included in the solid-state imaging apparatus according to the embodiment of the present disclosure.

FIG. 4 is a cross-sectional view depicting an example of configuration of the pixel group included in the solid-state imaging apparatus according to the embodiment of the present disclosure.

FIG. 5 is a block diagram depicting an example of circuit configuration of the solid-state imaging apparatus according to the embodiment of the present disclosure.

FIG. 6 is a block diagram depicting an example of configuration of a pixel circuit of the solid-state imaging apparatus according to the embodiment of the present disclosure.

FIG. 7 is a circuit diagram depicting an example of configuration of a decoder provided in the solid-state imaging apparatus according to the embodiment of the present disclosure.

FIG. 8 is a circuit diagram depicting an example of configuration of a detecting circuit provided in the solid-state imaging apparatus according to the embodiment of the present disclosure.

FIG. 9 is a circuit diagram depicting an example of configuration of a selection circuit provided in the solid-state imaging apparatus according to the embodiment of the present disclosure.

FIG. 10 is a timing diagram depicting an example of operation of the solid-state imaging apparatus according to the embodiment of the present disclosure.

FIG. 11 is a plan view depicting an example of configuration of a pixel group included in a solid-state imaging apparatus according to modification example 1 of the embodiment of the present disclosure.

FIG. 12 is a cross-sectional view depicting an example of configuration of the pixel group included in the solid-state imaging apparatus according to the modification example 1 of the embodiment of the present disclosure.

FIG. 13 is a plan view depicting an example of configuration of a pixel group included in a solid-state imaging apparatus according to modification example 2 of the embodiment of the present disclosure.

FIG. 14 is a cross-sectional view depicting an example of configuration of the pixel group included in the solid-state imaging apparatus according to the modification example 2 of the embodiment of the present disclosure.

FIG. 15 is a plan view depicting an example of configuration of a pixel group included in a solid-state imaging apparatus according to modification example 3 of the embodiment of the present disclosure.

FIG. 16 is a cross-sectional view depicting an example of configuration of the pixel group included in the solid-state imaging apparatus according to the modification example 3 of the embodiment of the present disclosure.

FIG. 17 is a block diagram depicting an example of schematic configuration of a vehicle control system.

FIG. 18 is a diagram of assistance in explaining an example of installation positions of an outside-vehicle information detecting section and an imaging section.

### DESCRIPTION OF EMBODIMENT

A detailed description will be given below of a mode for carrying out the present disclosure (embodiment) with reference to drawings. The description given below is merely a specific example of the present disclosure, and the present disclosure is not limited to the embodiment given below.

### <Distance Measurement System>

A distance measurement system according to an embodiment of the present disclosure is a system for measuring a distance to a subject by using a structured light technique. Also, the distance measurement system according to the present embodiment can be also used as a system that acquires a three-dimensional (3D) image and can be, in this case, referred to as a three-dimensional image acquisition system. In the structured light technique, the distance is measured by identifying coordinates of a point image and from which light source (i.e. point light source) the point image is projected through pattern matching.

### [System Configuration]

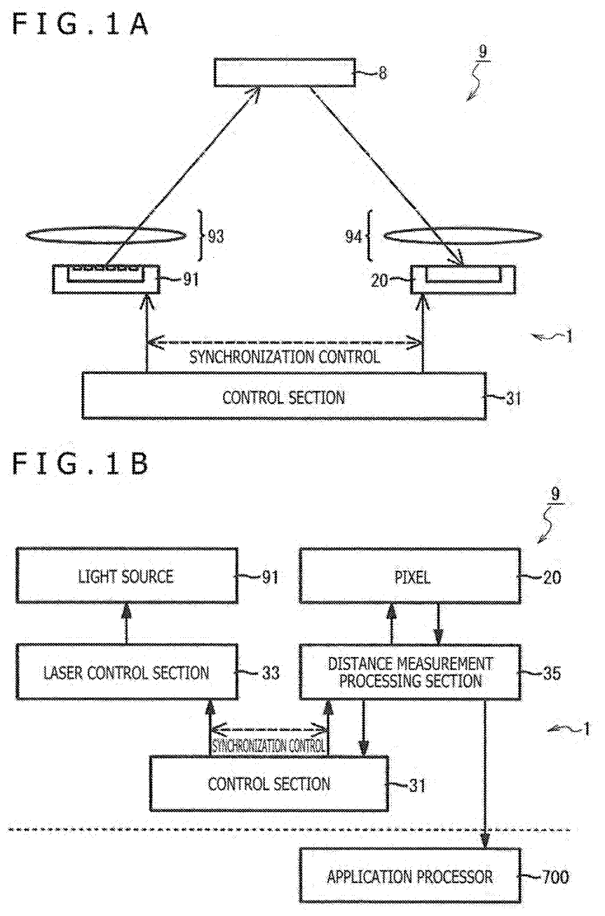

FIG. 1A is a schematic diagram depicting an example of configuration of the distance measurement system according to the present embodiment. FIG. 1B is a block diagram depicting an example of circuit configuration of the distance measurement system according to the present embodiment.

A distance measurement system 9 according to the present embodiment includes a light source 91 that emits light onto a subject 8. The light source 91 includes a surface emission semiconductor laser such as a vertical resonator surface emission laser. The distance measurement system 9 includes a solid-state imaging apparatus 1 according to the present embodiment (described in detail later). A plurality of pixels 20 included in the solid-state imaging apparatus 1 functions as light-receiving sections in the distance measurement system 9. The light source 91 emits a high-frequency laser beam onto the subject 8. As depicted in FIGS. 1A and 1B, the distance measurement system 9 according to the present embodiment includes not only the light source 91 and the plurality of pixels 20 but also a control section 31, a laser control section 33, a distance measurement processing section 35, a light source-side optics 93, and an imaging apparatus-side optics 94.

The control section 31, the laser control section 33, the distance measurement processing section 35, and the plurality of pixels 20 will be described in detail later. The control section 31 drives the light source 91 via the laser control section 33 and controls the plurality of pixels 20 and the distance measurement processing section 35. More specifically, the control section 31 controls the light source 91, the plurality of pixels 20, and the distance measurement processing section 35 by synchronizing these sections.

In the distance measurement system 9 according to the present embodiment, the high-frequency laser beam emitted from the light source 91 is applied onto the subject 8 (i.e., target to be measured) through the light source-side optics 93. This beam emitted is reflected by the subject 8. The beam reflected by the subject 8 enters into the plurality of pixels 20 through the imaging apparatus-side optics 94. The distance measurement processing section 35 measures the distance between the solid-state imaging apparatus 1 and the subject 8 by using the TOF (Time Of Flight) technique. Distance information measured by the distance measurement processing section 35 is supplied to an application processor 700 external to the distance measurement system 9. The application processor 700 performs a given process on the input distance information.

### <Schematic Configuration of Solid-State Imaging Apparatus>

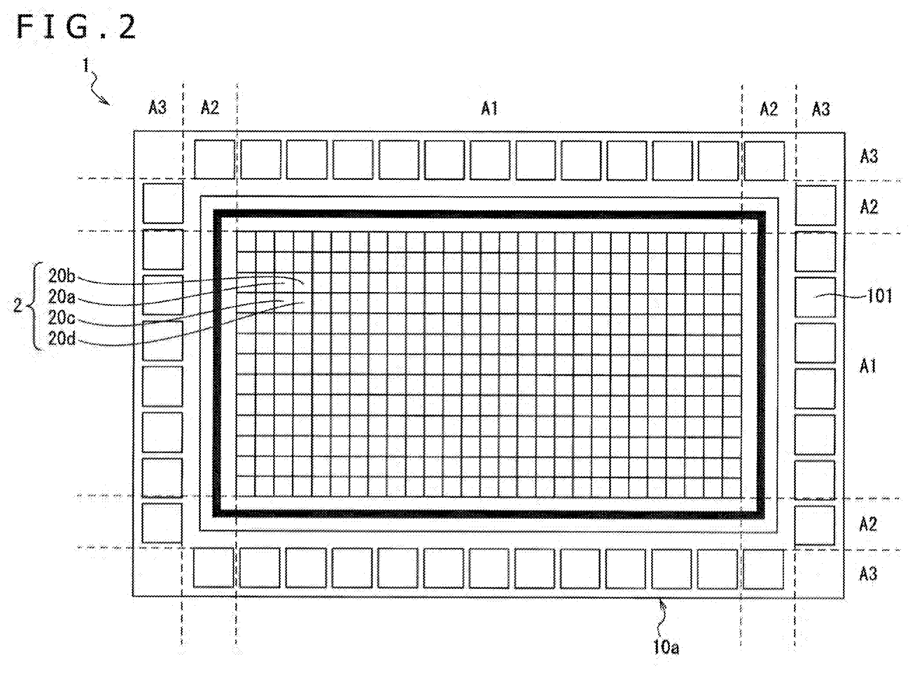

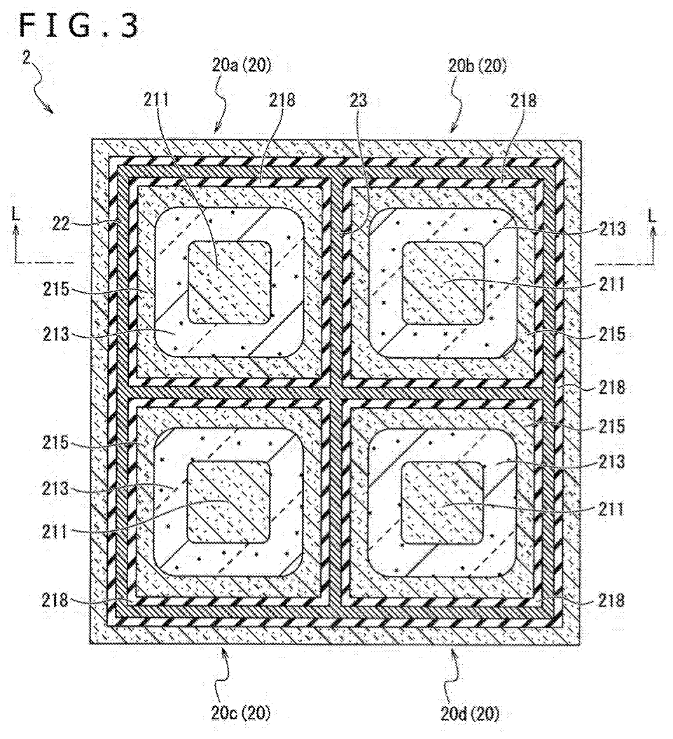

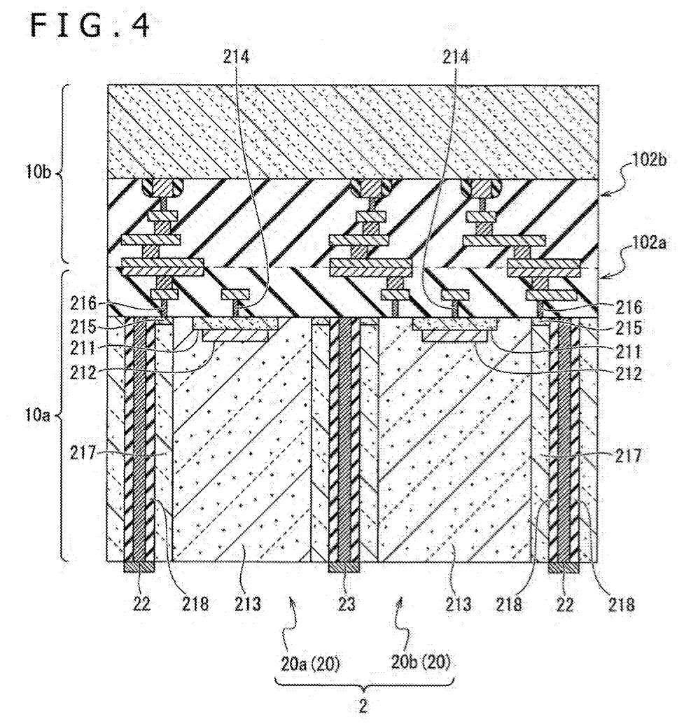

A description will be given next of schematic configuration of the solid-state imaging apparatus 1 according to the present embodiment by using FIGS. 2 to 4. FIG. 2 is a schematic diagram depicting an example of planar configuration of the solid-state imaging apparatus 1. FIG. 3 is a plan view depicting an example of configuration of a pixel group 2 included in the solid-state imaging apparatus 1. FIG. 4 is a cross-sectional view depicting an example of configuration of the pixel group 2 cut along line L-L in FIG. 3.

As depicted in FIG. 2, the solid-state imaging apparatus 1 according to the present embodiment has a sensor chip 10a and a logic chip 10b (not depicted in FIG. 2). A pixel region A1, a surrounding region A2, and a pad region A3 are provided on the sensor chip 10a. The logic chip 10b is arranged on a lower surface (surface on the opposite side of a light entry surface) of the sensor chip 10a. The pixel region A1 is, for example, a rectangular region that stretches from a center to an edge portion side of the sensor chip 10a. The surrounding region A2 is an annular region provided so as to surround the pixel region A1. The pad region A3 is an annular region provided so as to surround the surrounding region A2 and provided on an outermost perimeter side of the sensor chip 10a.

The pixel region A1 has the plurality of pixels 20 that is arranged in an array pattern. All the pixels 20 provided in the pixel region A1 have the same configuration. In FIG. 2, the pixels 20 are represented by white rectangles. Also, in FIG. 2, reference signs “20a, 20b, 20c, and 20d” are assigned only to four pixels of the plurality of pixels 20 to facilitate the understanding. The pixels will be collectively referred to as the pixels 20 below in a case where the pixels 20a, 20b, 20c, and 20d are described without distinction and in a case where all the pixels 20 provided in the pixel region A1 are described.

The solid-state imaging apparatus 1 includes the plurality of pixel groups 2 each of which has the plurality of pixels 20 (four pixels in the present embodiment). In FIG. 2, a reference sign “2” is assigned only to those pixel groups having the pixels 20a, 20b, 20c, and 20d of the plurality of pixel groups 2.

As depicted in FIG. 2, the pad region A3 is formed such that pad opening portions 101 which are vertical holes extending from the upper edge of the sensor chip 10a into a wiring layer 102a (not depicted in FIG. 2; refer to FIG. 4) and wiring holes leading to electrode pads (not depicted) are arranged in a straight line. In FIG. 2, the pad opening portions 101 are represented by white rectangles. Also, in FIG. 2, a reference sign is assigned only to one of the plurality of pad opening portions 101 to facilitate the understanding. A wiring electrode pad is provided on a bottom of each of the pad opening portions 101. This electrode pad is used for connection to wiring in the wiring layer 102a or to other external apparatuses (e.g., chip). Also, a wiring layer close to a bonding surface between the sensor chip 10a and the logic chip 10b can also be used as an electrode pad.

Each of the wiring layer 102a formed in the sensor chip 10a and a wiring layer 102b formed in the logic chip 10b (not depicted in FIG. 2; refer to FIG. 4) includes an insulating film and a plurality of pieces of wiring, and the plurality of pieces of wiring and the electrode pads include, for example, a metal such as copper (Cu) or aluminum (Al). Wiring formed in the pixel region A1 and the surrounding region A2 includes a material similar to that of the plurality of pieces of wiring and the electrode pads formed in the wiring layers 102a and 102b.

As depicted in FIG. 2, the surrounding region A2 is provided between the pixel region A1 and the pad region A3. The surrounding region A2 includes an n-type semiconductor region and a p-type semiconductor region. Also, the p-type semiconductor region is connected to wiring (not depicted) formed in the surrounding region A2 via a contact portion (not depicted). The wiring is connected to ground (GND). A trench (not depicted) is formed between the pixel region A1 and the surrounding region A2. The trench is provided to reliably separate the pixel region A1 from the surrounding region A2.

Although described later, a light-receiving element 21 (not depicted in FIG. 2; refer to FIGS. 3 and 4) including an avalanche photon diode is provided in the pixel 20. A high voltage is applied between a cathode and an anode of the light-receiving element 21. Also, the surrounding region A2 is connected to the GND. For this reason, a high electric field region occurs because of the application of a high voltage to the anode of the light-receiving element 21 in the region between the pixel region A1 and the surrounding region A2, which may result in a breakdown. A possible solution to avoid the breakdown would be to widen the region (separation region) provided between the pixel region A1 and the surrounding region A2. However, widening the separation region results in a larger size of the sensor chip 10a. Accordingly, the trench is formed in the present embodiment to prevent such a breakdown and upsizing of the sensor chip 10a. This trench makes it possible to prevent the breakdown without widening the separation region.

As depicted in FIG. 3, the pixel group 2 has the four pixels 20a, 20b, 20c, and 20d that are arranged in an array pattern. The pixels 20a, 20b, 20c, and 20d are arranged adjacent to each other. The pixel group 2 has a first light-shielding section 22 and a second light-shielding section 23. The first light-shielding section 22 is provided to surround an outer perimeter of the pixel group 2. The second light-shielding section 23 is provided in boundary portions of the plurality of pixels 20a, 20b, 20c, and 20d. The first light-shielding section 22 and the second light-shielding section 23 include a metallic material such as W (tungsten), Al (aluminum), or Cu (copper) or other material such as polysilicon. The first light-shielding section 22 can prevent leakage of light reflected by the subject (not depicted in FIG. 3; refer to FIG. 1) into the adjacent pixel groups 2. Also, the second light-shielding section 23 can prevent leakage of light reflected by the subject 8 into the adjacent pixels 20.

Each of the pixels 20a, 20b, 20c, and 20d has the light-receiving element 21 that converts received light into an electric signal. The light-receiving element 21 is, for example, an avalanche photon diode (APD) that multiplies carriers by using the high electric field region. The APD has a Geiger mode and a linear mode. The Geiger mode causes the APD to operate at a bias voltage higher than a breakdown voltage. The linear mode causes the APD to operate at a bias voltage close to and slightly higher than the breakdown voltage. The avalanche photon diode in the Geiger mode is also referred to as a single photon avalanche diode (SPAD). The SPAD is a device that can detect a single photon for each pixel 20 by multiplying carriers, which are generated by photoelectric conversion, in the PN junction region having a high electric field that is provided for each pixel 20. In the present embodiment, the light-receiving element 21 includes, for example, an SPAD which is a type of APD. This makes it possible for the light-receiving element 21 to improve light detection accuracy. The configuration of the pixel 20 will be described in detail later.

As depicted in FIG. 4, the logic chip 10b is connected and arranged on the lower surface of the sensor chip 10a. Peripheral circuits (described in detail later) are formed on the logic chip 10b to process signals input from the pixels 20 and supply power to pixel circuits (described in detail later) provided in the pixels 20. In the example depicted in FIG. 4, the sensor chip 10a and the logic chip 10b are electrically connected such that, of the wiring layers formed on the side of the bonding surface between the sensor chip 10a and the logic chip 10b in the pixel region A1, some of the outermost wiring layers on the side of the bonding surface are directly joined together.

(Pixel configuration)

A description will be given next of a detailed configuration of the pixels included in the solid-state imaging apparatus 1 according to the present embodiment. The solid-state imaging apparatus 1 includes the back-illuminated pixels 20. That is, the sensor chip 10a is arranged on the side of a back surface of the solid-state imaging apparatus 1, and the logic chip 10b is arranged on the side of a front surface of the solid-state imaging apparatus 1. The pixels 20 are stacked on top of an on-chip lens (not depicted) into which light enters. The wiring layer 102a is stacked on top of the pixels 20. The logic chip 10b is stacked on top of the wiring layer 102a with the wiring layer 102b placed face to face with the wiring layer 102a.

Light enters into the pixels 20 from the side of the on-chip lens. In a case of the back-illuminated pixels 20, the pixel circuits for driving the pixels 20 are formed, for example, in the wiring layer 102a and the wiring layer 102b provided on the logic chip 10b. Also, the peripheral circuits for driving the pixel circuits are formed, for example, in the wiring layer 102b provided on the logic chip 10b. Also, the circuits may be arranged in the same substrate by arranging the circuits in a region outside a pixel area.

The solid-state imaging apparatus 1 according to the present embodiment is applicable both to the back-illuminated pixels 20 depicted in FIG. 4 and front-illuminated pixels that are arranged below the on-chip lens. A description will be given below of the pixel included in the solid-state imaging apparatus 1 by citing an example of the back-illuminated pixel 20.

As depicted in FIG. 4, the pixel 20 has the light-receiving element 21 that includes the SPAD. The light-receiving element 21 has an n-type semiconductor region 211 whose conduction type is n type (first conduction type). The light-receiving element 21 has a p-type semiconductor region 212 that is formed under the n-type semiconductor region 211 and whose conduction type is p type (second conduction type). The n-type semiconductor region 211 and the p-type semiconductor region 212 are formed in a well layer 213.

The well layer 213 may be a semiconductor region whose conduction type is n type or a semiconductor region whose conduction type is p type. Also, the well layer 213 is prone to depletion, for example, in a case where the well layer 213 is a low-concentration n- or p-type semiconductor region of the order of 1×10¹⁴ or less. The depletion of the well layer 213 makes it possible to improve detection efficiency which is referred to as PDE (PhotonDetecti on Efficiency).

The n-type semiconductor region 211 includes, for example, Si (silicon) and is a semiconductor region having high impurity concentration and whose conduction type is n type. The p-type semiconductor region 212 includes, for example, Si (silicon) and is a semiconductor region having high impurity concentration and whose conduction type is p type. The p-type semiconductor region 212 forms the pn junction at an interface with the n-type semiconductor region 211. The p-type semiconductor region 212 has a multiplication region that multiplies, by avalanche multiplication, carriers that occur as a result of entry of light to be detected. The p-type semiconductor region 212 may be depleted. The depletion of the p-type semiconductor region 212 makes it possible to improve the PDE.

The n-type semiconductor region 211 functions as a cathode of the light-receiving element 21. The n-type semiconductor region 211 is connected to the pixel circuit (not depicted in FIG. 4) via a contact 214 and the wiring. An anode 215 of the light-receiving element 21 that is paired with the cathode is formed in the same layer as the n-type semiconductor region 211 so as to surround the n-type semiconductor region 211 (refer to FIG. 3). The anode 215 is formed between the n-type semiconductor region 211 and an oxide film 218 formed on a side wall of each of the first light-shielding section 22 and the second light-shielding section 23. The anode 215 is connected to a power supply (not depicted) provided in the peripheral circuit via the contact 216 and the wiring.

Not only the first light-shielding section 22 and the oxide film 218 but also the second light-shielding section 23 and the oxide film 218 function as separation regions for separating the pixels 20 from each other. A hole accumulation region 217 is formed between the oxide film 218 and the well layer 213. The hole accumulation region 217 is formed under the anode 215. The hole accumulation region 217 is electrically connected to the anode 215. The hole accumulation region 217 can be formed, for example, as a p-type semiconductor region. The hole accumulation region 217 can be formed by ion implantation, solid phase diffusion, induction by a fixed charge film, or other means.

The hole accumulation region 217 is formed in a portion where different materials are in contact. In the example depicted in FIG. 4, the material included in the oxide film 218 and that included in the well layer 213 are different. Accordingly, if the oxide film 218 and the well layer 213 are in contact, there is a possibility that a dark current may occur at the interface between the two. Therefore, the formation of the hole accumulation region 217 between the oxide film 218 and the well layer 213 makes it possible to suppress the dark current.

In a case where the light-receiving element 21 including an APD is used in the back-illuminated solid-state imaging apparatus, the on-chip lens (not depicted) is, for example, stacked under the well layer 213 (the side opposite to that where the n-type semiconductor region 211 is formed). A hole accumulation region may be formed at the interface with the well layer 213 on the side where the on-chip lens is formed.

Meanwhile, in a case where the light-receiving element 21 including an APD is used in the front-illuminated solid-state imaging apparatus, a silicon substrate is, for example, arranged under the well layer 213 (the side opposite to that where the n-type semiconductor region 211 is formed). Accordingly, in a case where the light-receiving element 21 including the APD is used in the front-illuminated solid-state imaging apparatus, pixel configuration in which no hole accumulation region is formed can be adopted. Needless to say, even in a case where the light-receiving element 21 including the APD is used in the front-illuminated solid-state imaging apparatus, the hole accumulation region 217 may be formed under the well layer 213.

That is, the hole accumulation region 217 can be formed on a surface other than an upper surface (surface where the n-type semiconductor region 211 is formed) of the well layer 213. Alternatively, the hole accumulation region 217 can be formed on a surface other than the upper or lower surface of the well layer 213.

The first light-shielding section 22, the second light-shielding section 23, and the oxide film 218 are formed between the adjacent pixels 20 to separate the light-receiving elements 21 formed in the pixels 20 from each other. That is, the first light-shielding section 22, the second light-shielding section 23, and the oxide film 218 are formed such that multiplication regions are formed in one-to-one correspondence with the light-receiving elements 21. The first light-shielding section 22, the second light-shielding section 23, and the oxide film 218 are formed in a two-dimensional grid pattern so as to fully surround a circumference of each of the n-type semiconductor regions 211 (i.e., multiplication regions) (refer to FIG. 3). The first light-shielding section 22, the second light-shielding section 23, and the oxide film 218 are formed so as to penetrate the well layer 213 from an upper surface side to a lower surface side in a stacking direction. The first light-shielding section 22, the second light-shielding section 23, and the oxide film 218 may be configured so as to not only fully penetrate the well layer 213 from the upper surface side to the lower surface side but also, for example, penetrate the well layer 213 only partially from the upper surface side to the lower surface side and be inserted halfway through the substrate.

As depicted in FIG. 3, the pixels 20a, 20b, 20c, and 20d provided in the pixel group 3 are separated by the second light-shielding section 23 and the oxide film 218 that are formed in the grid pattern. The anode 215 is formed inside the second light-shielding section 23. The well layer 213 is formed between the anode 215 and the n-type semiconductor region 211. The n-type semiconductor region 211 is formed at a center portion of the light-receiving elements 21.

Although the hole accumulation region 217 is not visible when seen from above, the hole accumulation region 217 is formed inside the second light-shielding section 23. In other words, the hole accumulation region 217 is formed in a region approximately the same as that of the anode 215.

The shape of the n-type semiconductor region 211 when seen from above is not limited to a rectangle and may be a circle. In a case where the n-type semiconductor region 211 is formed in the shape of the rectangle as depicted in FIG. 3, a wide area can be secured as the multiplication region (the n-type semiconductor region 211), which makes it possible to improve the detection efficiency which is referred to as the PDE. In a case where the n-type semiconductor region 211 is formed in the shape of the circle, electric field concentration can be suppressed at the edge portion of the n-type semiconductor region 211, which makes it possible to reduce unintended edge breakdown.

As described above, the formation of the hole accumulation region 217 at the interface can cause electrons that occur at the interface to be trapped, which makes it possible to suppress a DCR (dark current rate). Also, the pixels 20 in the present embodiment are configured so as to trap electrons by accumulating holes with the hole accumulation region 217. However, the pixels 20 may be configured so as to trap holes by accumulating electrons. The DCR can be suppressed even in a case where the pixels 20 are configured so as to trap holes.

Also, the solid-state imaging apparatus 1 can reduce at least one of electrical crosstalk and optical crosstalk by including the first light-shielding section 22, the second light-shielding section 23, the oxide film 218, and the hole accumulation region 217. Also, the provision of the hole accumulation region 217 on a side surface of the pixels 20 causes a lateral electric field to be formed, which makes it easier to collect carriers in the high electric field region and makes it possible to improve the PDE.

### <Circuit Configuration of Solid-State Imaging Apparatus>

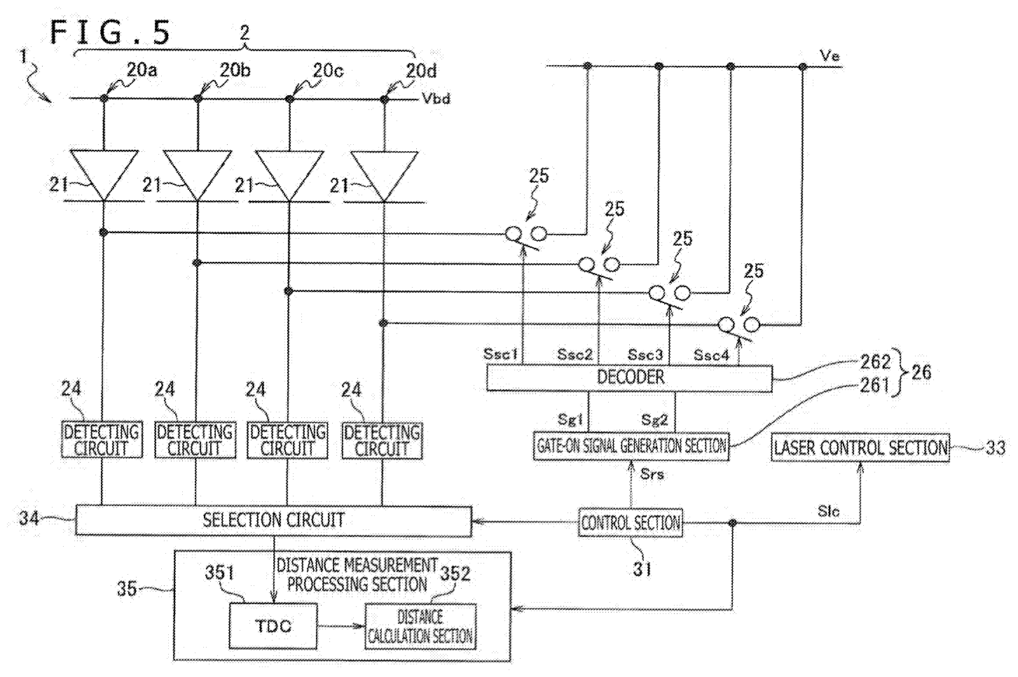

A description will be given next of the peripheral circuits and the pixel circuits included in the solid-state imaging apparatus 1 according to the present embodiment with reference to FIGS. 2 to 4 and by using FIGS. 5 to 9.

As depicted in FIG. 5, the solid-state imaging apparatus 1 includes a control section 31 that integrally controls the peripheral circuits and the pixel circuits included in the solid-state imaging apparatus 1. The control section 31 includes, for example, a central processing unit (CPU). The solid-state imaging apparatus 1 includes a laser control section 33, a pixel driving section (example of driving section) 26, and a distance measurement processing section 35 that are connected to the control section 31.

The control section 31 is configured so as to output a light emission control signal Slc to the laser control section 33 and the distance measurement processing section 35. Also, the control section 31 is configured so as to output a distance measurement start signal Srs to the pixel driving section 26. The control section 31 synchronizes the light emission control signal Slc and the distance measurement start signal Srs and outputs these signals to the laser control section 33, the distance measurement processing section 35, and the pixel driving section 26.

The pixel driving section 26 included in the solid-state imaging apparatus 1 is configured so as to drive the pixels 20a, 20b, 20c, and 20d by shifting operation timings of the light-receiving elements 21 provided in the pixels 20a, 20b, 20c, and 20d, respectively. The pixel driving section 26 has a gate-on signal generation section (example of signal generation section) 261 that generates gate control signals Sg1 and Sg2 (examples of signals) in response to input of the distance measurement start signal Srs (example of synchronizing signal) that is synchronous with the light emission control signal Slc that controls the emission of light from the light source 91. Also, the pixel driving section 26 has a decoder 262 that is controlled by the signals generated by the gate-on signal generation section 261 to output control signals Ssc1, Ssc2, Ssc3, and Ssc4 that control switching elements 25 (described in detail later).

The distance measurement processing section 35 included in the solid-state imaging apparatus 1 is provided such that an electric signal obtained by photoelectric conversion of the light-receiving element 21 is input from each of the pixels 20a, 20b, 20c, and 20d and includes a time measurement section 351 that measures, on the basis of the input of the electric signal, the time until light emitted from the light source 91 (not depicted in FIG. 5; refer to FIG. 1) is reflected by the subject (not depicted in FIG. 5; refer to FIG. 1) and received by the light-receiving element 21. The time measurement section 351 includes, for example, a time-to-digital converter that converts time information of an analog signal based on the electric signal output from the light-receiving element 21 into time information of a digital signal. The light emission control signal Slc is input to the time measurement section 351. The time measurement section 351 measures, in response to the input of the light emission control signal Slc as a trigger, the time until light emitted from the light source 91 is reflected by the subject 8 and received by the light-receiving element 21. Also, the time measurement section 351 ends the measurement of the time in response to the input of a detection signal from a detecting circuit 24 (described in detail later) via a selection circuit 34 on the basis of the electric signal output from the light-receiving element 21 as a trigger.

The distance measurement processing section 35 included in the solid-state imaging apparatus 1 has a distance calculation section 352 that calculates a distance to the subject 8 on the basis of time information output from the time measurement section 351. The distance measurement processing section 35 is configured so as to measure the distance between the solid-state imaging apparatus 1 and the subject 8 by using the ToF (Time of Flight) technique. Specifically, time information including time of flight of light ΔT is input to the distance calculation section 352 from the time measurement section 351. The time of flight of light ΔT corresponds to the time until light emitted from the light source 91 is reflected by the subject 8 and received by the light-receiving element 21. The time measurement section 351 acquires the time of flight of light ΔT by calculating a difference (te-ts) between time is when the measurement of the time until light emitted from the light source 91 is reflected by the subject 8 and is received by the light-receiving element 21 and time to when the measurement ends. The distance calculation section 352 calculates a distance D between the solid-state imaging apparatus 1 and the subject 8 by using Formula (1) given below. It should be noted that “c” in Formula (1) represents a speed of light.

D=(c/2)×(te−ts) (1)

The laser control section 33 emits a laser beam onto the subject 8 in response to the input of the light emission control signal Slc as a trigger. The gate-on signal generation section 261 outputs the gate control signals Sg1 and Sg2 to the decoder 262 in response to the input of the distance measurement start signal Srs as a trigger. Although described in detail later, the pixel 20 starts light detection operation of the light-receiving element 21 in response to the output of the gate control signals Sg1 and Sg2 as a trigger. Also, the distance measurement processing section 35 starts the measurement of the time until light emitted from the light source 91 is reflected by the subject 8 and received by the light-receiving element 21 in response to the input of the light emission control signal Slc as a trigger. This makes it possible for the solid-state imaging apparatus 1 to synchronize the start of the output of the laser beam from the light source 91 with the start of the reception of light by the light-receiving element 21 and the start of the time measurement by the distance measurement processing section 35.

Each of the pixels 20a, 20b, 20c, and 20d has the switching element 25 that is connected between the cathode of the avalanche photon diode included in the light-receiving element 21 and a power supply Ve. The pixel driving section 26 generates the control signals Ssc1, Ssc2, Ssc3, and Ssc4 that control the switching elements 25 into and out of conduction. In the present embodiment, the decoder 262 provided in the pixel driving section 26 generates the control signals Ssc1, Ssc2, Ssc3, and Ssc4. The switching element 25 and the decoder 262 will be described in detail later.

Each of the pixels 20a, 20b, 20c, and 20d has the detecting circuit 24 to which the electric signal output from the light-receiving element 21 is input. The detecting circuit 24 includes, for example, an inverter circuit. The detecting circuit 24 will be described in detail later.

The solid-state imaging apparatus 1 includes the selection circuit 34 that is connected between the detecting circuit 24 and the time measurement section 351. The selection circuit 34 outputs, under control of the control section 31, an output signal of the detecting circuit 24 provided in any one of the pixels 20a, 20b, 20c, and 20d to the time measurement section 351. The selection circuit 34 will be described in detail later.

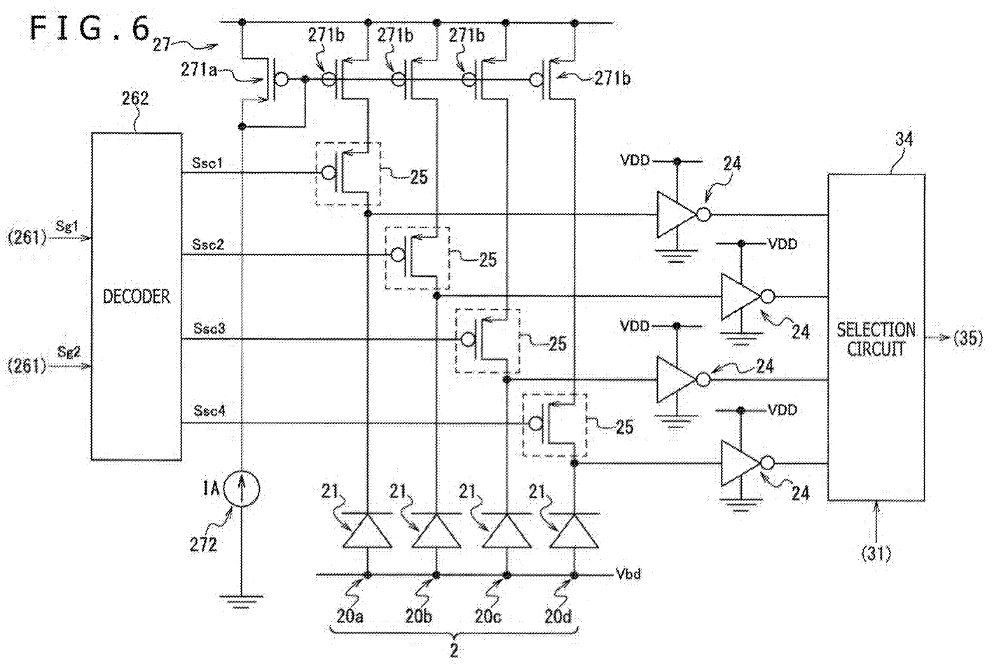

The control section 31, the laser control section 33, the gate-on signal generation section 261, and the distance measurement processing section 35 are formed in the surrounding region A2 and the pad region A3 and included in the peripheral circuits. Also, the decoder 262, the switching elements 25, the detecting circuits 24, the selection circuit 34, and a power supply circuit 27 (not depicted in FIG. 5; refer to FIG. 6) which will be described later are formed in the pixel region A1 and included in the pixel circuits. The decoder 262, the switching elements 25, the detecting circuits 24, and the selection circuit 34 are provided for each pixel group 2.

As depicted in FIG. 6, the switching element 25 included in each of the pixels 20a, 20b, 20c, and 20d includes a P-type transistor. A gate of the switching element 25 is connected to an output terminal of the decoder 262. More specifically, the gate of the switching element 25 provided in the pixel 20a is connected to the output terminal of the decoder 262 from which the control signal Ssc1 is output. The gate of the switching element 25 provided in the pixel 20b is connected to the output terminal of the decoder 262 from which the control signal Ssc12 is output. The gate of the switching element 25 provided in the pixel 20c is connected to the output terminal of the decoder 262 from which the control signal Ssc3 is output. The gate of the switching element 25 provided in the pixel 20d is connected to the output terminal of the decoder 262 from which the control signal Ssc4 is output.

Accordingly, the switching element 25 provided in the pixel 20a is in conduction (is ON) in a case where the control signal Ssc1 is at low voltage level and is out of conduction (is OFF) in a case where the control signal Ssc1 is at high voltage level. The switching element 25 provided in the pixel 20b is in conduction (is ON) in a case where the control signal Ssc2 is at low voltage level and is out of conduction (is OFF) in a case where the control signal Ssc2 is at high voltage level. The switching element 25 provided in the pixel 20c is in conduction (is ON) in a case where the control signal Ssc3 is at low voltage level and is out of conduction (is OFF) in a case where the control signal Ssc3 is at high voltage level. The switching element 25 provided in the pixel 20d is in conduction (is ON) in a case where the control signal Ssc4 is at low voltage level and is out of conduction (is OFF) in a case where the control signal Ssc4 is at high voltage level. The decoder 262 is configured so as to set the voltage of any one of the control signals Ssc1, Ssc2, Ssc3, and Ssc4 to low level and the remaining voltages to high level. Accordingly, the pixel driving section 26 can drive the pixel group 2 such that any one of the pixels 20a, 20b, 20c, and 20d provided in the pixel group 2 is in conduction and the remaining pixels are out of conduction.

The switching element 25 provided in the pixel 20a has a source connected to the power supply circuit 27 (described in detail later) and a drain connected to the cathode of the light-receiving element 21 provided in the pixel 20a. The switching element 25 provided in the pixel 20b has the source connected to the power supply circuit 27 and the drain connected to the cathode of the light-receiving element 21 provided in the pixel 20b. The switching element 25 provided in the pixel 20c has the source connected to the power supply circuit 27 and the drain connected to the cathode of the light-receiving element 21 provided in the pixel 20c. The switching element 25 provided in the pixel 20d has the source connected to the power supply circuit 27 and the drain connected to the cathode of the light-receiving element 21 provided in the pixel 20d.

The detecting circuit 24 provided in the pixel 20a has an input terminal and an output terminal. The input terminal is connected to a drain of the switching element 25 provided in the pixel 20a and to the cathode of the light-receiving element 21. The output terminal is connected to the selection circuit 34. The detecting circuit 24 provided in the pixel 20b has the input terminal and the output terminal. The input terminal is connected to the drain of the switching element 25 provided in the pixel 20b and to the cathode of the light-receiving element 21. The output terminal is connected to the selection circuit 34. The detecting circuit 24 provided in the pixel 20c has the input terminal and the output terminal. The input terminal is connected to the drain of the switching element 25 provided in the pixel 20c and to the cathode of the light-receiving element 21. The output terminal is connected to the selection circuit 34. The detecting circuit 24 provided in the pixel 20d has the input terminal and the output terminal. The input terminal is connected to the drain of the switching element 25 provided in the pixel 20d and to the cathode of the light-receiving element 21. The output terminal is connected to the selection circuit 34.

As depicted in FIG. 6, the pixel group 2 has the power supply circuit 27 that is connected to the light-receiving element 21 via the switching element 25. The power supply circuit 27 has a current mirror circuit 271 and a constant current source 272. The constant current source 272 supplies a constant current to the current mirror circuit 271. The current mirror circuit 271 has a P-type transistor 271a that is connected to the constant current source 272 and four P-type transistors 271b that are connected to the P-type transistor 271a.

The constant current source 272 and the P-type transistor 271a are connected in series between the power supply Ve and the ground (GND). The P-type transistor 271a has the source connected to the output terminal of the constant current source 272 and the drain connected to the power supply Ve. The gate of the P-type transistor 271a is connected to the source of the P-type transistor 271a and to each of the gates of the four P-type transistors 271b.

The P-type transistor 272b provided in the pixel 20a has the source connected to the power supply Ve and the drain connected to the source of the switching element 25 provided in the pixel 20a. The P-type transistor 272b provided in the pixel 20b has the source connected to the power supply Ve and the drain connected to the source of the switching element 25 provided in the pixel 20b. The P-type transistor 272b provided in the pixel 20c has the source connected to the power supply Ve and the drain connected to the source of the switching element 25 provided in the pixel 20c. The P-type transistor 272b provided in the pixel 20d has the source connected to the power supply Ve and the drain connected to the source of the switching element 25 provided in the pixel 20d.

The four P-type transistors 272b have the same transistor size. The P-type transistor 272a is formed in a transistor size that allows it to pass a desired current to each of the four P-type transistors 272b. This makes it possible for the current mirror circuit 271 to pass the same and desired current to the light-receiving elements 21 provided in the pixels 20a, 20b, 20c, and 20d, respectively.

The anode of the light-receiving element 21 provided in each of the pixels 20a, 20b, 20c, and 20d is connected to a power supply Vbd. The power supply Vbd is configured, for example, so as to output a voltage of −20V. The power supply Ve is configured, for example, so as to output a voltage of +3V to +5V. Accordingly, in a case where the switching element 25 is in conduction, the voltage of −20V is applied to the anode of the light-receiving element 21, and the voltage of +3V to +5V is applied to the cathode thereof. This causes a voltage higher than the breakdown voltage to be applied to the light-receiving element 21. If the light-receiving element 21 receives light in this state, the avalanche amplification occurs, which causes a current to flow. The flow of the current through the light-receiving element 21 reduces the cathode voltage of the light-receiving element 21.

When the switching element 25 is out of conduction or before the current flows through the light-receiving element 21, approximately the same voltage as the output voltage of the power supply Ve is, for example, input to the input terminal of the detecting circuit 24. Accordingly, the detecting circuit 24 outputs a low-level voltage. Meanwhile, when the cathode voltage level drops below 0V as a result of the flow of the current through the light-receiving element 21, the detecting circuit 24 outputs a high-level voltage.

The output terminals of the four detecting circuits 24 are connected to the selection circuit 34. Accordingly, output signals of the four detecting circuits 24 are input to the selection circuit 34. A selection signal is input to the selection circuit 34 from the control section 31. The selection circuit 34 outputs any one of the output signals of the four detecting circuits 24 to the distance measurement processing section 35 on the basis of the selection signal.

A description will be given here of a specific configuration of the decoder 262 by using FIG. 7.

As depicted in FIG. 7, the decoder 262 has inverter gates 262a and 262b provided on its input side and NAND gates 262c, 262d, 262e, and 262f provided on its output side. The input terminal of the inverter gate 262a and the input terminal of the inverter gate 262b are used as the input terminals of the decoder 262. The gate control signal Sg1 is input to the input terminal of the inverter gate 262a. The gate control signal Sg2 is input to the input terminal of the inverter gate 262b.

The input terminal of the inverter gate 262a is connected to one of the input terminals of each of the NAND gates 262e and 262f. The output terminal of the inverter gate 262a is connected to one of the input terminals of each of the NAND gates 262c and 262d. The input terminal of the inverter gate 262b is connected to the other input terminal of each of the NAND gates 262d and 262f. The output terminal of the inverter gate 262b is connected to the other input terminal of each of the NAND gates 262c and 262e.

The output terminals of the NAND gates 262c, 262d, 262e, and 262f are used as the output terminals of the decoder 262. The output control signal Ssc1 is, for example, output from the output terminal of the NAND gate 262c. The output control signal Ssc2 is, for example, output from the output terminal of the NAND gate 262d. The output control signal Ssc3 is, for example, output from the output terminal of the NAND gate 262e. The output control signal Ssc4 is, for example, output from the output terminal of the NAND gate 262f.

In a case where both the gate control signals Sg1 and Sg2 are at low voltage level, the control signal Ssc1 is at low voltage level, and the control signals Ssc2, Ssc3, and Ssc4 are at high voltage level. This drives only the switching element 25 provided in the pixel 20a (refer to FIG. 6) into conduction and the remaining switching elements 25 (refer to FIG. 6) out of conduction. In a case where the gate control signal Sg1 is at low voltage level and the gate control signal Sg2 is at high voltage level, the control signal Ssc2 is at low voltage level, and the control signals Ssc1, Ssc3, and Ssc4 are at high voltage level. This drives only the switching element 25 provided in the pixel 20b into conduction and the remaining switching elements 25 out of conduction. In a case where the gate control signal Sg1 is at high voltage level and the gate control signal Sg2 is at low voltage level, the control signal Ssc3 is at low voltage level, and the control signals Ssc1, Ssc2, and Ssc4 are at high voltage level. This drives only the switching element 25 provided in the pixel 20c into conduction and the remaining switching elements 25 out of conduction. In a case where both the gate control signals Sg1 and Sg2 are at high voltage level, the control signal Ssc4 is at low voltage level, and the control signals Ssc1, Ssc2, and Ssc3 are at high voltage level. This drives only the switching element 25 provided in the pixel 20d into conduction and the remaining switching elements 25 out of conduction.

As described above, the decoder 262 can control any one of the four switching elements 25 into conduction and the remaining switching elements 25 out of conduction. Because the pixel driving section 26 is operating synchronously with the laser control section 33, the voltage levels of the gate control signals Sg1 and Sg2 can be changed synchronously with the output of the laser beam from the light source 91. This makes it possible for the decoder 262 to sequentially switch the voltage levels of the control signals Ssc1, Ssc2, and Ssc4 synchronously with the output of the laser beam from the light source 91. As a result, the solid-state imaging apparatus 1 can sequentially enable the light-receiving elements 21 provided, respectively, in the pixels 20a, 20b, 20c, and 20d to detect light.

A description will be given next of a specific configuration of the detecting circuit 24.

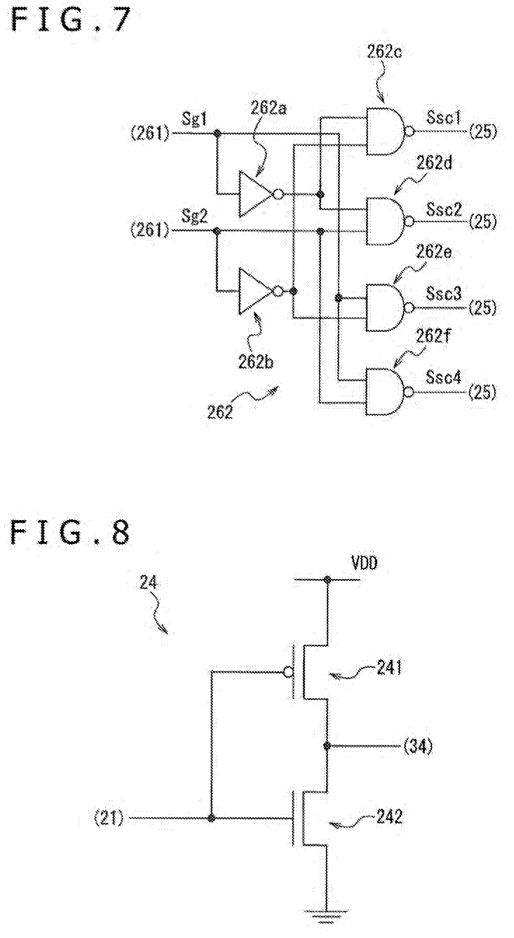

As depicted in FIG. 8, the detecting circuit 24 has a P-type transistor 241 and an N-type transistor 242 that are connected in series between a power supply VDD and the ground. The gate of the P-type transistor 241 and the gate of the N-type transistor 242 are connected to each other. A connection portion between the gate of the P-type transistor 241 and the gate of the N-type transistor 242 is used as the input terminal of the detecting circuit 24. The source of the P-type transistor 241 is connected to the power supply VDD. The source of the N-type transistor 242 is connected to the ground. The drain of the P-type transistor 241 and the drain of the N-type transistor 242 are connected to each other. The connection portion between the drain of the P-type transistor 241 and the drain of the N-type transistor 242 is used as the output terminal of the detecting circuit 24.

Such a configuration allows the detecting circuit 24 to output an electric signal at high voltage level in a case where an electric signal at low voltage level is input and to output an electric signal at low voltage level in a case where an electric signal at high voltage level is input. As described above, in a case where the light-receiving element 21 is not receiving light, the cathode voltage of the light-receiving element 21 is approximately the same as the output voltage of the power supply Ve and at high level (e.g., 3V to 5V). Accordingly, in a case where the light-receiving element 21 is not receiving light, the detecting circuit 24 outputs a detection signal at low voltage level. Meanwhile, in a case where the light-receiving element 21 receives light, the cathode voltage of the light-receiving element 21 is approximately the same as the output voltage of the power supply Vbd and at low level (e.g., −20V). Accordingly, in a case where the light-receiving element 21 is receiving light, the detecting circuit 24 outputs the detection signal at high voltage level.

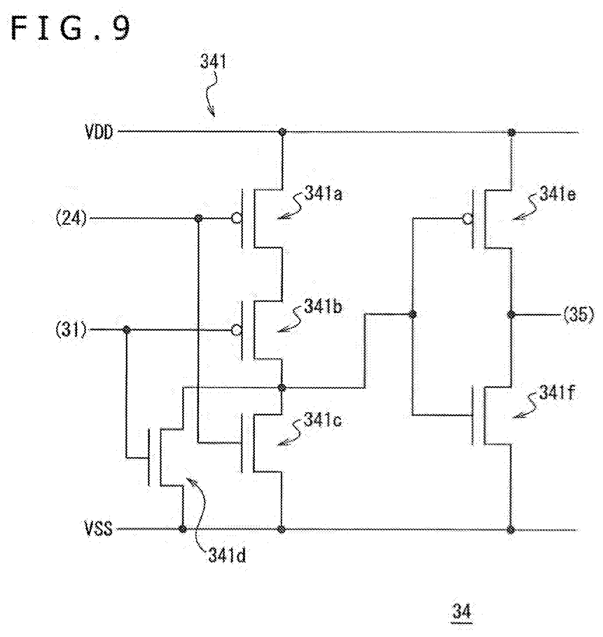

A description will be given next of a specific configuration of the selection circuit 34. The selection circuit 34 has a logical circuit that is connected to each detecting circuit 24. As depicted in FIG. 9, the logical circuit is, for example, a logical sum circuit. That is, the selection circuit 34 has as many OR circuits (example of logical sum circuits) 341 depicted in FIG. 9 as the number of the detecting circuits 24.

The OR circuit 341 has two P-type transistors 341a and 341b and one N-type transistor 341c that are connected in series between the power supply VDD and a reference potential VSS that is at the same voltage level as the ground. The gate of the P-type transistor 341a is used as one of the input terminals of the OR circuit 341 and connected, for example, to the output terminal of the detecting circuit 24. The gate of the P-type transistor 341b is used as the other input terminal of the OR circuit 341 and connected, for example, to the control section 31. The source of the P-type transistor 341a is connected to the power supply VDD. The drain of the P-type transistor 341a is connected to the source of the P-type transistor 341b. The source of the N-type transistor 242 is connected to the reference potential VSS. The drain of the N-type transistor 341c and the drain of the P-type transistor 341b are connected to each other.

The OR circuit 341 has an N-type transistor 341d that is connected between the connection portion between the drains of the N-type transistor 341c and the P-type transistor 341b and the reference potential VSS. The gate of the N-type transistor 341d is connected to the gate of the P-type transistor 341b.

The OR circuit 341 has a P-type transistor 341e and an N-type transistor 341f that are connected between the power supply VDD and the reference potential VSS. The gate of the P-type transistor 341e and the gate of the N-type transistor 341f are connected to each other. The connection portion between the gate of the P-type transistor 341e and the gate of the N-type transistor 341f is connected to the connection portion between the drain of the N-type transistor 341c and the drain of the P-type transistor 341b. The source of the P-type transistor 341e is connected to the power supply VDD. The source of the N-type transistor 341f is connected to the reference potential VSS. The drain of the P-type transistor 341e and the drain of the N-type transistor 341f are connected to each other. The connection portion between the drain of the P-type transistor 341e and the drain of the N-type transistor 341f is used as the output terminal of the OR circuit 341.

In a case where a selection signal at high voltage level is input from the control section 31, the OR circuit 341 outputs a signal at the voltage level of the power supply VDD. Meanwhile, in a case where the selection signal at low voltage level is input from the control section 31, the OR circuit 341 outputs the same signal as the detection signal input from the detecting circuit 24. Accordingly, the selection circuit 34 can select one of the detection signals of the four detecting circuits 24 on the basis of the selection signal input from the control section 31 and outputs the detection signal to the distance measurement processing section 35.

### <Operation of Solid-State Imaging Apparatus>

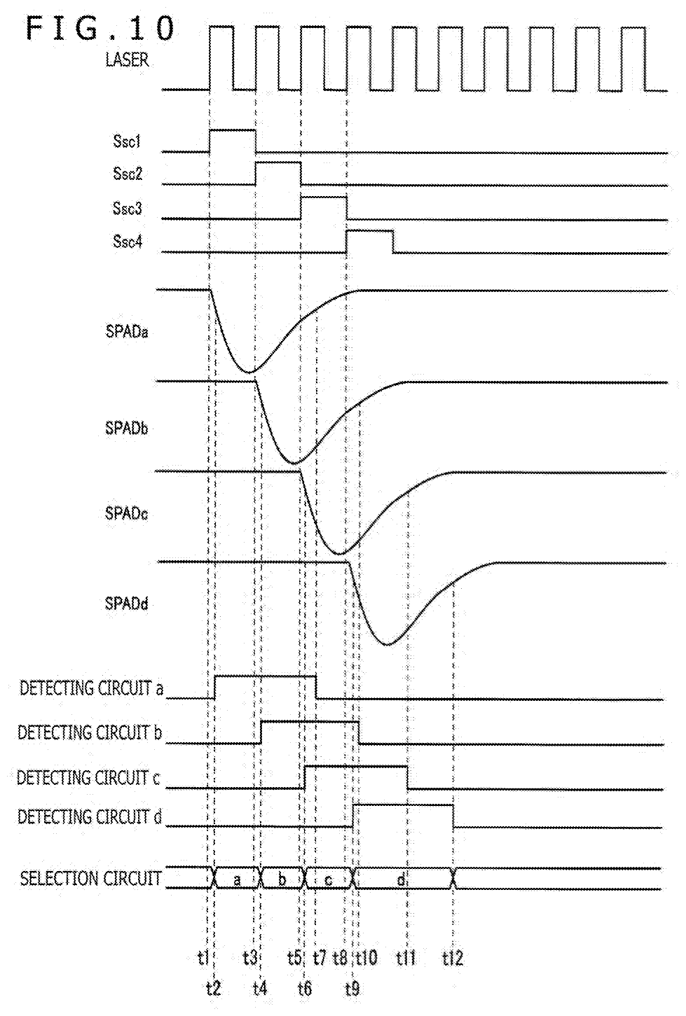

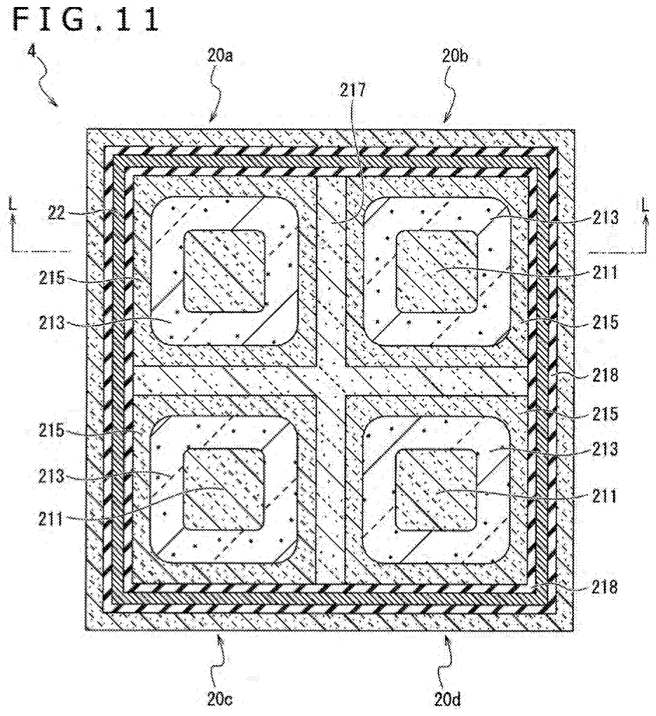

A description will be given next of operation of the solid-state imaging apparatus 1 according to the present embodiment with reference to FIGS. 5 and 6 and by using FIG. 10. FIG. 10 is a timing diagram depicting an example of operation of the solid-state imaging apparatus 1. “Laser” in FIG. 10 represents an emission pattern of the laser beam output from the light source 91. The high level of the emission pattern represents a time period of the laser beam emission. “Ssc1, Ssc2, Ssc3, Ssc4” in FIG. 10 represents the control signals Ssc1, Ssc2, Ssc3, and Ssc4 output from the decoder 262.

“SPADa” in FIG. 10 represents a cathode voltage waveform of the light-receiving element 21 provided in the pixel 20a. “SPADb” in FIG. 10 represents the cathode voltage waveform of the light-receiving element 21 provided in the pixel 20b. “SPADc” in FIG. 10 represents the cathode voltage waveform of the light-receiving element 21 provided in the pixel 20c. “SPADd” in FIG. 10 represents the cathode voltage waveform of the light-receiving element 21 provided in the pixel 20d. “Detecting circuit a” in FIG. 10 represents a detection signal voltage waveform of the detecting circuit 24 provided in the pixel 20a. “Detecting circuit b” in FIG. 10 represents the detection signal voltage waveform of the detecting circuit 24 provided in the pixel 20b. “Detecting circuit c” in FIG. 10 represents the detection signal voltage waveform of the detecting circuit 24 provided in the pixel 20c. “Detecting circuit d” in FIG. 10 represents the detection signal voltage waveform of the detecting circuit 24 provided in the pixel 20d. “Selection circuit” in FIG. 10 represents the output signal of the selection circuit 34.

As depicted in FIG. 10, the control signal Ssc1 output from the decoder 262 goes to high voltage level synchronously with the start of the output of the laser beam from the light source 91 at time t1. This drives the switching element 25 provided in the pixel 20a into conduction. Thereafter, the reception of the laser beam reflected by the subject 8 by the light-receiving element 21 provided in the pixel 20a starts the flow of the current through the light-receiving element 21, which reduces the cathode voltage of the light-receiving element 21.

When the cathode voltage of the light-receiving element 21 provided in the pixel 20a reaches, for example, 0 volt (more precisely, the voltage lower than a threshold voltage of the transistor included in the detecting circuit 24) at time t2 in a given time period after time t1, the detection signal of the detecting circuit 24 provided in the pixel 20a changes from low voltage level to high voltage level. When a given time period elapses from time t2, the cathode voltage of the light-receiving element 21 falls below the voltage of the power supply Vbd which is the breakdown voltage, which stops the avalanche amplification. After the avalanche amplification has stopped in the light-receiving element 21, the cathode voltage of the light-receiving element 21 starts to return to the initial voltage of the power supply Ve again (recharging operation).

When the detection signal of the detecting circuit 24 provided in the pixel 20a goes to high level, the selection circuit 34 selects the detection signal of the detecting circuit 24 provided in the pixel 20a and outputs the signal to the time measurement section 351 provided in the distance measurement processing section 35 under control of the control section 31 (refer to FIG. 5).

The output of the laser beam from the light source 91 starts at time t3 after the recharging operation has started in the light-receiving element 21 provided in the pixel 20a. The control signal Ssc1 output from the decoder 262 goes to low voltage level, and the control signal Ssc2 goes to high voltage level synchronously with the output of the laser beam. This drives the switching element 25 provided in the pixel 20a out of conduction and the switching element 25 provided in the pixel 20b that is out of conduction into conduction. Thereafter, the reception of the laser beam reflected by the subject 8 by the light-receiving element 21 provided in the pixel 20b starts the flow of the current through the light-receiving element 21, which reduces the cathode voltage of the light-receiving element 21.

When the cathode voltage of the light-receiving element 21 provided in the pixel 20b reaches, for example, 0 volt (more precisely, the voltage lower than the threshold voltage of the transistor included in the detecting circuit 24) at time t4 in a given time period after time t3, the detection signal of the detecting circuit 24 provided in the pixel 20b changes from low voltage level to high voltage level. When a given time period elapses from time t4, the cathode voltage of the light-receiving element 21 falls below the voltage of the power supply Vbd which is the breakdown voltage, which stops the avalanche amplification. After the avalanche amplification has stopped in the light-receiving element 21, the cathode voltage of the light-receiving element 21 starts to return to the initial voltage of the power supply Ve again (recharging operation). When the recharging operation of the light-receiving element 21 provided in the pixel 20b starts, the light-receiving element 21 provided in the pixel 20a is continuing its recharging operation.

When the detection signal of the detecting circuit 24 provided in the pixel 20b goes to high level, the selection circuit 34 selects the detection signal of the detecting circuit 24 provided in the pixel 20b in place of the detection signal of the detecting circuit 24 provided in the pixel 20a and outputs the signal to the time measurement section 351 provided in the distance measurement processing section 35 under control of the control section 31.

The output of the laser beam from the light source 91 starts at time t5 after the recharging operation has started in the light-receiving element 21 provided in the pixel 20b. The control signal Ssc2 output from the decoder 262 goes to low voltage level, and the control signal Ssc3 goes to high voltage level synchronously with the output of the laser beam. This drives the switching element 25 provided in the pixel 20b out of conduction and the switching element 25 provided in the pixel 20c that is out of conduction into conduction. Thereafter, the reception of the laser beam reflected by the subject 8 by the light-receiving element 21 provided in the pixel 20c starts the flow of the current through the light-receiving element 21, which reduces the cathode voltage of the light-receiving element 21.

When the cathode voltage of the light-receiving element 21 provided in the pixel 20c reaches, for example, 0 volt (more precisely, the voltage lower than the threshold voltage of the transistor included in the detecting circuit 24) at time t6 in a given time period after time t5, the detection signal of the detecting circuit 24 provided in the pixel 20c changes from low voltage level to high voltage level. When a given time period elapses from time t6, the cathode voltage of the light-receiving element 21 falls below the voltage of the power supply Vbd which is the breakdown voltage, which stops the avalanche amplification. After the avalanche amplification has stopped in the light-receiving element 21, the cathode voltage of the light-receiving element 21 starts to return to the initial voltage of the power supply Ve again (recharging operation). When the recharging operation of the light-receiving element 21 provided in the pixel 20c starts, the light-receiving element 21 provided in the pixel 20a and the light-receiving element 21 provided in the pixel 20b are continuing their recharging operations, respectively.

When the detection signal of the detecting circuit 24 provided in the pixel 20c goes to high level, the selection circuit 34 selects the detection signal of the detecting circuit 24 provided in the pixel 20c in place of the detection signal of the detecting circuit 24 provided in the pixel 20b and outputs the signal to the time measurement section 351 provided in the distance measurement processing section 35 under control of the control section 31.

When the cathode voltage of the light-receiving element 21 provided in the pixel 20a reaches a voltage equal to or higher than the threshold voltage of the transistor included in the detecting circuit 24 provided in the pixel 20a at time t7 in a given time period after time t6, the detection signal output from the detecting circuit 24 changes from low voltage level to high voltage level.

The output of the laser beam from the light source 91 starts at time t8 in a given time period after time t7 when the detection signal output from the detecting circuit 24 provided in the pixel 20a changes to low voltage level. The control signal Ssc3 output from the decoder 262 goes to low voltage level, and the control signal Ssc4 goes to high voltage level synchronously with the output of the laser beam. This drives the switching element 25 provided in the pixel 20c out of conduction and the switching element 25 provided in the pixel 20d that is out of conduction into conduction. Thereafter, the reception of the laser beam reflected by the subject 8 by the light-receiving element 21 provided in the pixel 20d starts the flow of the current through the light-receiving element 21, which reduces the cathode voltage of the light-receiving element 21.

When the cathode voltage of the light-receiving element 21 provided in the pixel 20d reaches, for example, 0 volt (more precisely, the voltage lower than the threshold voltage of the transistor included in the detecting circuit 24) at time t9 in a given time period after time t8, the detection signal of the detecting circuit 24 provided in the pixel 20d changes from low voltage level to high voltage level. When a given time period elapses from time t9, the cathode voltage of the light-receiving element 21 falls below the voltage of the power supply Vbd which is the breakdown voltage, which stops the avalanche amplification. After the avalanche amplification has stopped in the light-receiving element 21, the cathode voltage of the light-receiving element 21 starts to return to the initial voltage of the power supply Ve again (recharging operation). When the recharging operation of the light-receiving element 21 provided in the pixel 20c starts, the light-receiving element 21 provided in the pixel 20a, the light-receiving element 21 provided in the pixel 20b, and the light-receiving element 21 provided in the pixel 20c are continuing their recharging operations.

When the detection signal of the detecting circuit 24 provided in the pixel 20d goes to high level, the selection circuit 34 selects the detection signal of the detecting circuit 24 provided in the pixel 20d in place of the detection signal of the detecting circuit 24 provided in the pixel 20c and outputs the signal to the time measurement section 351 provided in the distance measurement processing section 35 under control of the control section 31.

When the cathode voltage of the light-receiving element 21 provided in the pixel 20b reaches the voltage equal to or higher than the threshold voltage of the transistor included in the detecting circuit 24 provided in the pixel 20b at time t10 in a given time period after time t9, the detection signal output from the detecting circuit 24 changes from low voltage level to high voltage level. Also, the light-receiving element 21 provided in the pixel 20a ends its recharging operation at time t10.

When the cathode voltage of the light-receiving element 21 provided in the pixel 20c reaches the voltage equal to or higher than the threshold voltage of the transistor included in the detecting circuit 24 provided in the pixel 20c at time t11 in a given time period after time t10, the detection signal output from the detecting circuit 24 changes from high voltage level to low voltage level. Also, the light-receiving element 21 provided in the pixel 20b ends its recharging operation at time t11.

When the cathode voltage of the light-receiving element 21 provided in the pixel 20d reaches the voltage equal to or higher than the threshold voltage of the transistor included in the detecting circuit 24 provided in the pixel 20d at time t12 in a given time period after time t11, the detection signal output from the detecting circuit 24 changes from high voltage level to low voltage level. Also, the light-receiving element 21 provided in the pixel 20c ends its recharging operation at time t12. Further, when a given time period elapses from time t12, the light-receiving element 21 provided in the pixel 20d ends its recharging operation. The solid-state imaging apparatus 1 repeats the operations from time t1 to time t12. It should be noted, however, that the control signal Ssc4 output from the decoder 262 goes to low voltage level, and the control signal Ssc1 goes to high voltage level synchronously with the first output of the laser beam from the light source 91 after the recharging operation of the light-receiving element 21 provided in the pixel 20c has started.

Incidentally, the time period during which the light-receiving element 21 performs its recharging operation is the time period during which the light-receiving element 21 cannot receive light. Here, if attention is focused, for example, on the light-receiving element 21 provided in the pixel 20a, the recharging operation time period of the light-receiving element 21 provided in the pixel 20a is from a given time slightly earlier than time t3 to time t10. Accordingly, the light-receiving element 21 cannot receive the laser beam emitted onto the subject 8 and reflected thereby at time t3, time t5, and time t8. Accordingly, in a case where a conventional solid-state imaging apparatus operates at the timings depicted in FIG. 10, the solid-state imaging apparatus cannot receive the laser beam only once out of four laser beam emissions. Therefore, the conventional solid-state imaging apparatus cannot receive the high-frequency laser beam, and there is a limit to increasing the frequency of the laser beam. Accordingly, the conventional solid-state imaging apparatus cannot achieve a sufficient frame rate and has a problem in that distance measurement takes a long time.

In contrast, the solid-state imaging apparatus 1 according to the present embodiment is configured so as to drive the pixels 20a, 20b, 20c, and 20d provided in the pixel group 2 by shifting the operation timings thereof. Also, in the solid-state imaging apparatus 1, the pixels 20a, 20b, 20c, and 20d provided in the pixel group 2 are connected to the single time measurement section 351. This makes it possible for the solid-state imaging apparatus 1 to input detection signals whose timings have been shifted to the time measurement section 351 from the detecting circuits 24 provided in the pixels 20a, 20b, 20c, and 20d, respectively. This makes it possible for the solid-state imaging apparatus 1 to detect high-frequency pulsed light. This makes it possible for the solid-state imaging apparatus 1 to achieve a sufficient frame rate and reduce the time required for distance measurement.

### MODIFICATION EXAMPLE 1

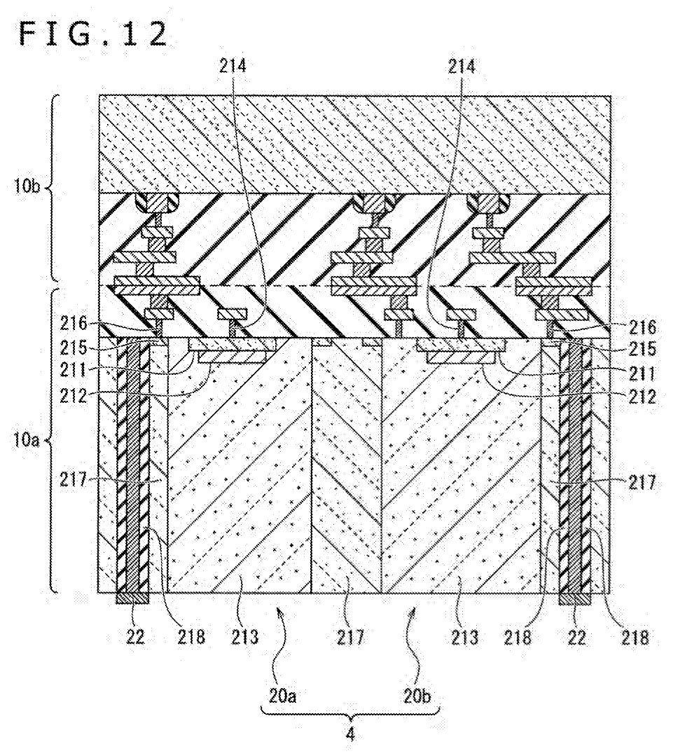

A description will be given next of a solid-state imaging apparatus according to modification example 1 of the present embodiment by using FIGS. 11 and 12. The solid-state imaging apparatus according to the present modification example is characterized in that it does not include the second light-shielding section 23 unlike the solid-state imaging apparatus 1 according to the above embodiment. It should be noted that components having the same actions and functions as those of the solid-state imaging apparatus 1 according to the above embodiment will be denoted by the same reference signs, and the description thereof will be omitted.

As depicted in FIG. 11, the solid-state imaging apparatus according to the present modification example includes a pixel group 4 that has the plurality of pixels 20a, 20b, 20c, and 20d (four pixels in the present embodiment). The pixels 20a, 20b, 20c, and 20d are arranged adjacent to each other. As depicted in FIGS. 11 and 12, the pixel group 4 has the first light-shielding section (example of light-shielding section) 22 that is provided to surround the outer perimeter of the pixel group 4, and no light-shielding section is provided between the adjacent pixels of the pixels 20a, 20b, 20c, and 20d. That is, no light-shielding section is provided between the pixels 20a and 20b, between the pixels 20a and 20c, and between the pixels 20b and 20d.

The hole accumulation region 217 is provided between the pixels 20a and 20b, between the pixels 20a and 20c, and between the pixels 20b and 20d. The pixels 20a, 20b, 20c, and 20d are separated by the hole accumulation region 217.

The solid-state imaging apparatus according to the present modification example does not require any trench due to the fact that no light-shielding section is provided between the adjacent pixels of the pixels 20a, 20b, 20c, and 20d. This makes it possible to increase aperture ratios of the pixels 20a, 20b, 20c, and 20d, which makes it possible to improve sensitivity. Also, in the solid-state imaging apparatus according to the present modification example, in a case where any one of the pixels 20a, 20b, 20c, and 20d is active, the remaining pixels are inactive. Accordingly, the solid-state imaging apparatus according to the present modification example is less susceptible to light leakage caused by the fact that no light-shielding section is provided between the adjacent pixels of the pixels 20a, 20b, 20c, and 20d, compared with the conventional solid-state imaging apparatus.

Because the solid-state imaging apparatus according to the present modification example is similar in circuit configuration and operation to the solid-state imaging apparatus 1 according to the above embodiment, the description thereof will be omitted. Also, because the distance measurement system according to the present modification example is similar in configuration to the distance measurement system according to the above embodiment, the description thereof will be omitted.

As described above, the solid-state imaging apparatus and the distance measurement system according to the present modification example provide similar advantageous effects to those of the solid-state imaging apparatus 1 and the distance measurement system according to the above embodiment.

### MODIFICATION EXAMPLE 2

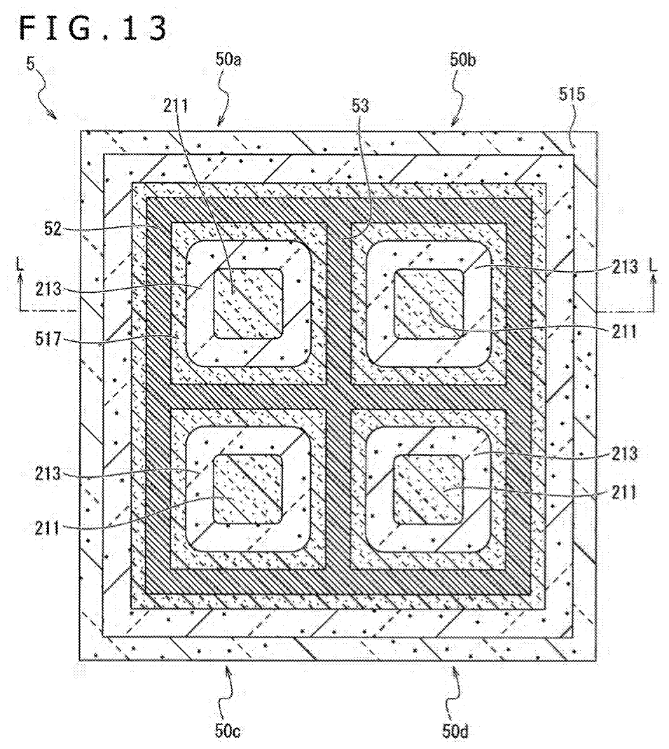

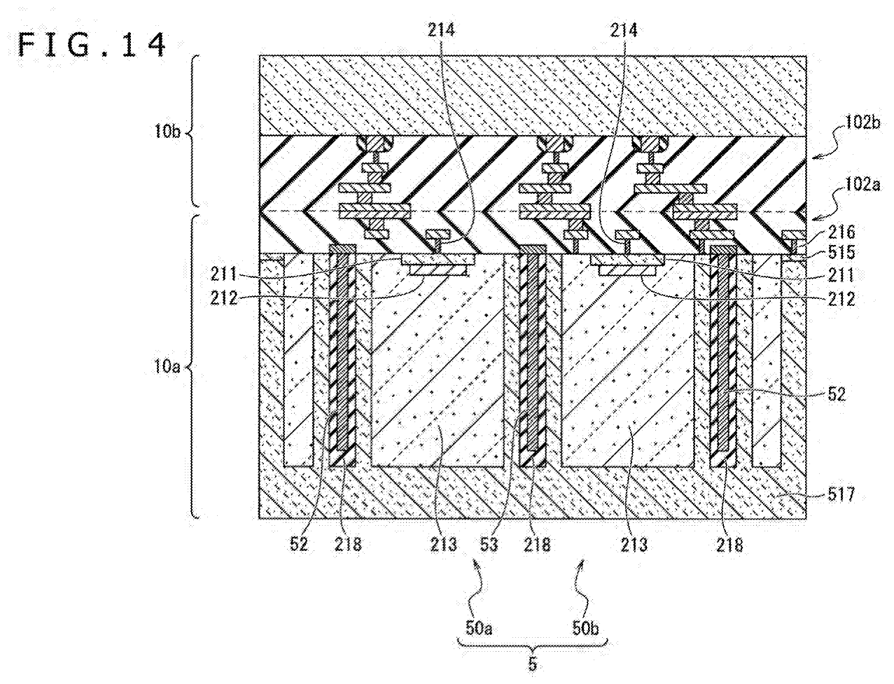

A description will be given next of a solid-state imaging apparatus according to modification example 2 of the present embodiment by using FIGS. 13 and 14. The solid-state imaging apparatus according to the present modification example is characterized in that the first light-shielding section 22 and the second light-shielding section 23 are not formed so as to penetrate the well layer 213 from the upper surface side to the lower surface side in the stacking direction, and that the respective cathodes of the plurality of pixels provided in the pixel group are shared unlike in the solid-state imaging apparatus 1 according to the above embodiment. It should be noted that the components having the same actions and functions as those of the solid-state imaging apparatus 1 according to the above embodiment will be denoted by the same reference signs, and the description thereof will be omitted.

As depicted in FIG. 12, the solid-state imaging apparatus according to the present modification example includes a pixel group 5 that has a plurality of pixels 50a, 50b, 50c, and 50d (four pixels in the present embodiment). The pixels 50a, 50b, 50c, and 50d are arranged adjacent to each other.

As depicted in FIG. 14, a first light-shielding section 52 and a second light-shielding section 53 provided in the pixel group 5 are not formed so as to penetrate the well layer 213 from the upper surface side to the lower surface side in the stacking direction. The first light-shielding section 52, the second light-shielding section 53, and an oxide film 518 penetrate only part of the well layer 213 from the upper surface side to the lower surface side and are inserted halfway through the substrate. The oxide film 518 is formed so as to also cover the lower surface sides of the first light-shielding section 52 and the second light-shielding section 53.

A hole accumulation region 517 is formed so as to cover not only the well layer 213 provided in each of the pixels 50a, 50b, 50c, and 50d but also the first light-shielding section 52, the second light-shielding section 53, and the oxide film 518. An anode 515 is formed in the same layer as the n-type semiconductor region 211 provided in each of the pixels 50a, 50b, 50c, and 50d. The anode 515 is formed so as to cover not only the well layer 213 provided in each of the pixels 50a, 50b, 50c, and 50d but also the first light-shielding section 52, the second light-shielding section 53, and the oxide film 518 and surround the hole accumulation region 517.

Because the solid-state imaging apparatus according to the present modification example is similar in circuit configuration and operation to the solid-state imaging apparatus 1 according to the above embodiment, the description thereof will be omitted. Also, because the distance measurement system according to the present modification example is similar in configuration to the distance measurement system according to the above embodiment, the description thereof will be omitted.

Even though the first light-shielding section 52, the second light-shielding section 53, and the oxide film 518 do not penetrate the well layer 213 and the anode 515 is shared by the pixels 50a, 50b, 50c, and 50d, the solid-state imaging apparatus and the distance measurement system according to the present modification example provide the similar advantageous effects to those of the solid-state imaging apparatus 1 and the distance measurement system according to the above embodiment.

### MODIFICATION EXAMPLE 3

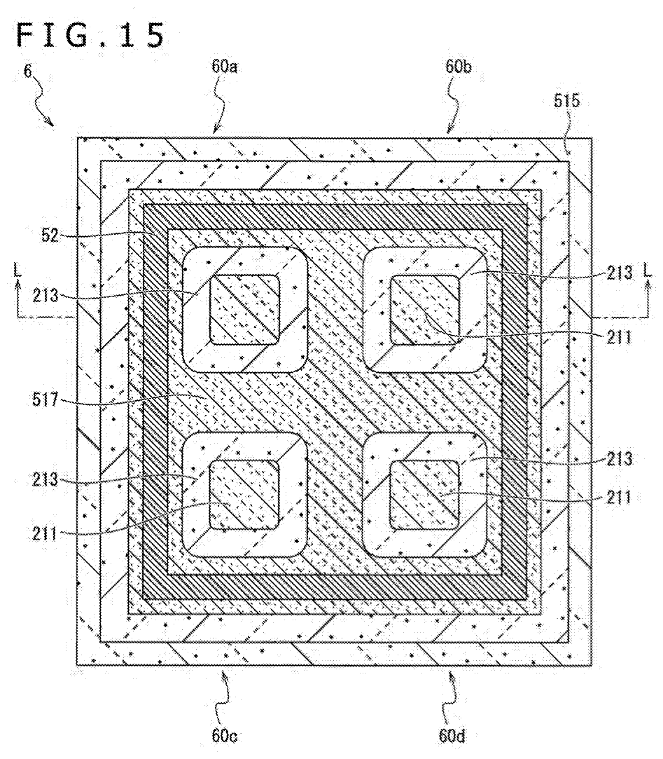

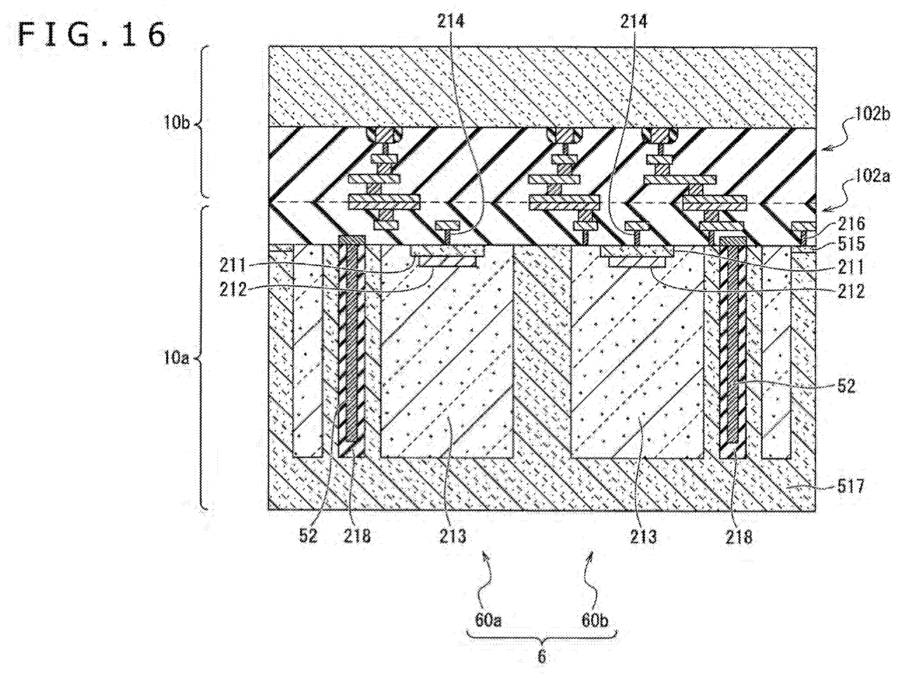

A description will be given next of a solid-state imaging apparatus according to modification example 3 of the present embodiment by using FIGS. 15 and 16. The solid-state imaging apparatus according to the present modification example is characterized in that it has characteristics of the solid-state imaging apparatuses according to modification examples 1 and 2 of the above embodiment. It should be noted that the components having the same actions and functions as those of the solid-state imaging apparatuses according to modification examples 1 and 2 of the above embodiment will be denoted by the same reference signs, and the description thereof will be omitted.

As depicted in FIG. 15, the solid-state imaging apparatus according to the present modification example includes a pixel group 6 that has a plurality of pixels 60a, 60b, 60c, and 60d (four pixels in the present embodiment). The pixels 60a, 60b, 60c, and 60d are arranged adjacent to each other. As depicted in FIGS. 15 and 16, the pixel group 6 has the first light-shielding section (example of light-shielding section) 52 that is provided to surround the outer perimeter of the pixel group 6, and no light-shielding section is provided between the adjacent pixels of the pixels 60a, 60b, 60c, and 60d. That is, no light-shielding section is provided between the pixels 60a and 60b, between the pixels 60a and 60c, and between the pixels 60b and 60d.

The hole accumulation region 517 is provided between the pixels 60a and 60b, between the pixels 60a and 60c, and between the pixels 60b and 60d. The pixels 60a, 60b, 60c, and 60d are separated by the hole accumulation region 517.

As depicted in FIG. 16, the first light-shielding section 52 provided in the pixel group 6 is not formed so as to penetrate the well layer 213 from the upper surface side to the lower surface side in the stacking direction. The first light-shielding section 52 and the oxide film 518 penetrate only part of the well layer 213 from the upper surface side to the lower surface side and are inserted halfway through the substrate. The oxide film 518 is formed so as to also cover the lower surface side of the first light-shielding section 52.

The hole accumulation region 517 is formed so as to cover not only the well layer 213 provided in each of the pixels 60a, 60b, 60c, and 60d but also the first light-shielding section 52 and the oxide film 518. The anode 515 is formed in the same layer as the n-type semiconductor region 211 provided in each of the pixels 50a, 50b, 50c, and 50d. The anode 515 is formed so as to cover not only the well layer 213 provided in each of the pixels 50a, 50b, 50c, and 50d but also the first light-shielding section 52 and the oxide film 518 and surround the hole accumulation region 517.

Because the solid-state imaging apparatus according to the present modification example is similar in circuit configuration and operation to the solid-state imaging apparatus 1 according to the above embodiment, the description thereof will be omitted. Also, because the distance measurement system according to the present modification example is similar in configuration to the distance measurement system according to the above embodiment, the description thereof will be omitted.

The solid-state imaging apparatus and the distance measurement system according to the present modification example provide the similar advantageous effects to those of the solid-state imaging apparatuses and the distance measurement systems according to the above embodiment and the above modification examples 1 and 2.

The present disclosure is not limited to the above embodiment and can be modified in various manners.

Although the pixel group has four pixels in the above embodiment and each of the modification examples, the present disclosure is not limited thereto. The pixel group may have two, three, or five or more pixels.

Although the solid-state imaging apparatuses according to the above embodiment and the respective modification examples have the selection circuit 34, the selection circuit 34 may not be provided, and the detecting circuit 24 provided in each pixel may be directly connected to the time measurement section 351.

Although the solid-state imaging apparatuses according to the above embodiment and the respective modification examples are configured so as to control the switching elements 25 by using the decoder 262, the present disclosure is not limited thereto. For example, the pixel driving section may have the signal generation section that generates the control signal for controlling the switching element provided in each pixel in response to the input of the synchronizing signal that is synchronous with the light emission control signal that controls the emission of light from the light source. That is, the pixel driving section 26 may be configured such that the gate-on signal generation section 261 generates the control signals Ssc1, Ssc2, Ssc3, and Ssc4 and outputs these signals to the switching elements 25. Also in this case, the solid-state imaging apparatus can individually control the switching elements 25 into and out of conduction, which provides the similar advantageous effects to those of the solid-state imaging apparatus according to the above embodiment.

### <Example of Application to Mobile Body>

The technology according to the present disclosure (present technology) is applicable to a variety of products. For example, the technology according to the present disclosure may be realized as an apparatus to be mounted on any type of mobile body such as automobiles, electric vehicles, hybrid electric vehicles, motorcycles, bicycles, personal transporters, airplanes, drones, ships, or robots.

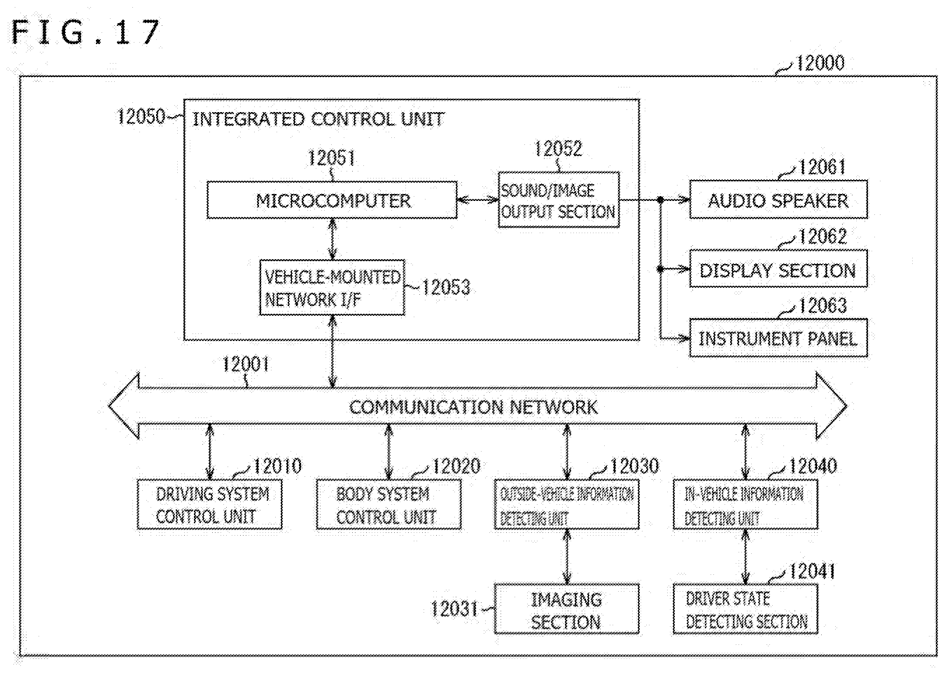

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

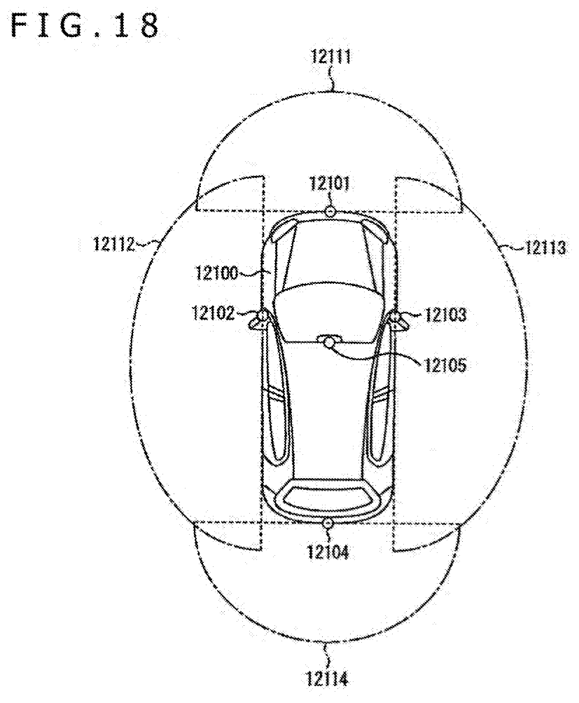

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure is applicable has been described above. The technology according to the present disclosure is applicable to the imaging section 12031 of those components described above.

Although the present disclosure has been described above by giving an example of the embodiment, the present disclosure is not limited to the above embodiment and the like and can be modified in various manners. It should be noted that the advantageous effects described in the present specification are merely illustrative. The advantageous effects of the present disclosure are not limited to those described in the present specification. The present disclosure may have advantageous effects other than those described in the present specification.

Also, the present disclosure can have the following configurations:
(1)
   A solid-state imaging apparatus including:
   a plurality of pixels each of which has a light-receiving element that converts received light into an electric signal;
   a drive section adapted to drive the plurality of pixels by shifting operation timings of the light-receiving elements; and
   a time measurement section provided such that the electric signal is input from each of the plurality of pixels and adapted to measure time until light emitted from a light source is reflected by a subject and received by the light-receiving element on the basis of the input of the electric signal.
(2)
   The solid-state imaging apparatus according to (1), in which
   the light-receiving element includes an avalanche photon diode that multiplies carriers by using a high electric field region.
(3)
   The solid-state imaging apparatus according to (2), in which
   each of the plurality of pixels has a switching element that is connected between a cathode of the avalanche photon diode and a power supply, and
   the drive section generates a control signal that controls the switching element into and out of conduction.
(4)
   The solid-state imaging apparatus according to (3), in which
   the drive section has
      a signal generation section that generates a signal in response to input of a synchronizing signal that is synchronous with a light emission control signal that controls emission of light from the light source, and
      a decoder that outputs the control signal under control of the signal generated by the signal generation section.
(5)
   The solid-state imaging apparatus according to (3), in which
   the drive section has a signal generation section that generates the control signal in response to input of a synchronizing signal that is synchronous with a light emission control signal that controls emission of light from the light source.
(6)
   The solid-state imaging apparatus according to any one of (1) to (5), in which
   each of the plurality of pixels has a detecting circuit to which the electric signal is input.
(7)
   The solid-state imaging apparatus according to (6), in which
   the detecting circuit is an inverter circuit.
(8)
   The solid-state imaging apparatus according to (6) or (7), including:
   a selection circuit connected between the detecting circuit and the time measurement section.
(9)
   The solid-state imaging apparatus according to (8), in which
   the selection circuit has a logical circuit that is connected to each detecting circuit.
(10)
   The solid-state imaging apparatus according to (9), in which
   the logical circuit is a logical sum circuit.
   The solid-state imaging apparatus according to any one of (1) to (10), in which
   the time measurement section is a time-to-digital converter that converts time information of an analog signal based on the electric signal into time information of a digital signal.
(12)
   The solid-state imaging apparatus according to any one of (1) to (11), including:
   a distance calculation section adapted to calculate a distance to the subject on the basis of time information output from the time measurement section.
(13)
   The solid-state imaging apparatus according to any one of (1) to (12), in which
   the plurality of pixels is arranged adjacent to each other.
(14)
   The solid-state imaging apparatus according to (13), including:
   a pixel group having the plurality of pixels, in which the pixel group has
      a first light-shielding section provided to surround an outer perimeter of the pixel group, and
      a second light-shielding section provided in boundary portions of the plurality of pixels.
(15)
   The solid-state imaging apparatus according to (13), including:
   a pixel group having the plurality of pixels, in which
   the pixel group has a light-shielding section provided to surround an outer perimeter of the pixel group, and
   no light-shielding section is provided between the adjacent pixels of the plurality of pixels.
(16)
   A distance measurement system including:
   a light source adapted to emit light onto a subject; and
   a solid-state imaging apparatus having a plurality of pixels each of which has a light-receiving element that converts received light into an electric signal, a drive section adapted to drive the plurality of pixels by shifting operation timings of the light-receiving elements; and a time measurement section provided such that the electric signal is input from each of the plurality of pixels and adapted to measure time until light emitted from the light source is reflected by the subject and received by the light-receiving element on the basis of the input of the electric signal.
(17)
   The distance measurement system according to (16), in which
   the light-receiving element is an avalanche photon diode element that multiplies carriers by using a high electric field region.

### REFERENCE SIGNS LIST

1: Solid-state imaging apparatus

2, 3, 4, 5, 6: Pixel group

8: Subject

9: Distance measurement system

10a: Sensor chip

10b: Logic chip

20, 20a, 20b, 20c, 20d, 50a, 50b, 50c, 50d, 60a, 60b, 60c, 60d: Pixel

21: Light-receiving element

22, 52: First light-shielding section

23, 53: Second light-shielding section

24: Detecting circuit

25: Switching element

26: Pixel driving section

27: Power supply circuit

31: Control section

33: Laser control section

34: Selection circuit

35: Distance measurement processing section

91: Light source

93: Light source-side optics

94: Imaging apparatus-side optics

101: Pad opening portion

102a: Wiring layer

102b: Wiring layer

211: n-type semiconductor region

212: p-type semiconductor region

213: Well layer

214, 216: Contact

215, 515: Anode

217, 517: Hole accumulation region

218, 518: Oxide film

241, 271a, 271b, 341e: P-type transistor

242: N-type transistor

261: Gate-on signal generation section

262: Decoder

262a, 262b: Inverter gate

262c, 262d, 262e, 262f: NAND gate

271: Current mirror circuit

272: Constant current source

341: OR circuit

341c, 341d, 341f: N-type transistor

351: Time measurement section

352: Distance calculation section

700: Application processor

A1: Pixel region

A2: Surrounding region

A3: Pad region

1. A solid-state imaging apparatus comprising:
a plurality of pixels each of which has a light-receiving element that converts received light into an electric signal;
a drive section adapted to drive the plurality of pixels by shifting operation timings of the light-receiving elements; and
a time measurement section provided such that the electric signal is input from each of the plurality of pixels and adapted to measure time until light emitted from a light source is reflected by a subject and received by the light-receiving element on a basis of the input of the electric signal.

2. The solid-state imaging apparatus according to claim 1, wherein
the light-receiving element includes an avalanche photon diode that multiplies carriers by using a high electric field region.

3. The solid-state imaging apparatus according to claim 2, wherein
each of the plurality of pixels has a switching element that is connected between a cathode of the avalanche photon diode and a power supply, and
the drive section generates a control signal that controls the switching element into and out of conduction.

4. The solid-state imaging apparatus according to claim 3, wherein
the drive section has
a signal generation section that generates a signal in response to input of a synchronizing signal that is synchronous with a light emission control signal that controls emission of light from the light source, and
a decoder that outputs the control signal under control of the signal generated by the signal generation section.

5. The solid-state imaging apparatus according to claim 3, wherein
the drive section has a signal generation section that generates the control signal in response to input of a synchronizing signal that is synchronous with a light emission control signal that controls emission of light from the light source.

6. The solid-state imaging apparatus according to claim 1, wherein
each of the plurality of pixels has a detecting circuit to which the electric signal is input.

7. The solid-state imaging apparatus according to claim 6, wherein
the detecting circuit is an inverter circuit.

8. The solid-state imaging apparatus according to claim 6, comprising:
a selection circuit connected between the detecting circuit and the time measurement section.

9. The solid-state imaging apparatus according to claim 8, wherein
the selection circuit has a logical circuit that is connected to each detecting circuit.

10. The solid-state imaging apparatus according to claim 9, wherein
the logical circuit is a logical sum circuit.

11. The solid-state imaging apparatus according to claim 1, wherein
the time measurement section is a time-to-digital converter that converts time information of an analog signal based on the electric signal into time information of a digital signal.

12. The solid-state imaging apparatus according to claim 1, comprising:
a distance calculation section adapted to calculate a distance to the subject on a basis of time information output from the time measurement section.

13. The solid-state imaging apparatus according to claim 1, wherein
the plurality of pixels is arranged adjacent to each other.

14. The solid-state imaging apparatus according to claim 13, comprising:
a pixel group having the plurality of pixels, wherein
the pixel group has
a first light-shielding section provided to surround an outer perimeter of the pixel group, and
a second light-shielding section provided in boundary portions of the plurality of pixels.

15. The solid-state imaging apparatus according to claim 13, comprising:
a pixel group having the plurality of pixels, wherein
the pixel group has a light-shielding section provided to surround an outer perimeter of the pixel group, and
no light-shielding section is provided between adjacent pixels of the plurality of pixels.

16. A distance measurement system comprising:
a light source adapted to emit light onto a subject; and
a solid-state imaging apparatus having a plurality of pixels each of which has a light-receiving element that converts received light into an electric signal, a drive section adapted to drive the plurality of pixels by shifting operation timings of the light-receiving elements, and a time measurement section provided such that the electric signal is input from each of the plurality of pixels and adapted to measure time until light emitted from the light source is reflected by the subject and received by the light-receiving element on a basis of the input of the electric signal.

17. The distance measurement system according to claim 16, wherein
the light-receiving element is an avalanche photon diode element that multiplies carriers by using a high electric field region.
